(19) United States
(12) Patent Application Publication
(10) Pub. No.: US 2025/0048646 A1
(43) Pub. Date: Feb. 6, 2025

(54) SEMICONDUCTOR DEVICE AND FABRICATION METHOD THEREOF AND MEMORY SYSTEM

(71) Applicant: YANGTZE MEMORY TECHNOLOGIES CO., LTD., Wuhan (CN)

(72) Inventors: Zhong Zhang, Wuhan (CN); Di Wang, Wuhan (CN); Dongxue Zhao, Wuhan (CN); Wenxi Zhou, Wuhan (CN); Zhiliang Xia, Wuhan (CN); Zongliang Huo, Wuhan (CN)

(21) Appl. No.: 18/381,073

(22) Filed: Oct. 17, 2023

Related U.S. Application Data
(63) Continuation of application No. PCT/CN2023/111269, filed on Aug. 4, 2023.

(51) Int. Cl. H10B 53/30; H01L 29/06; H10B 53/20

(52) U.S. Cl. CPC H10B 53/30; H01L 28/60; H01L 29/0653; H10B 53/20

(57) ABSTRACT

According to one aspect of the present disclosure, a semiconductor device is provided. The semiconductor device may include a stack structure including conductor layers and dielectric layers stacked alternately along a first direction. The semiconductor device may include at least one semiconductor structure penetrating through the stack structure. The semiconductor structure may include a capacitor structure, a first transistor structure, and a second transistor structure extending in the stack structure along the first direction. The second transistor structure, the first transistor structure, and the capacitor structure in a same semiconductor structure may be arranged and connected sequentially along the first direction.

### CROSS-REFERENCE TO RELATED APPLICATIONS

The present application is a continuation of International Application No. PCT/CN2023/111269, filed on Aug. 4, 2023, the content of which is incorporated herein by reference in its entirety.

### TECHNICAL FIELD

Examples of the present disclosure relate to the field of semiconductor technologies, and particularly to a semiconductor device and a fabrication method thereof, and a memory system.

### BACKGROUND

Ferroelectric random access memory (FeRAM), as a new memory, is utilized more and more widely as it has the advantages of nonvolatility, high rate and low power consumption as compared with traditional dynamic random access memory (DRAM).

### SUMMARY

According to one aspect of the present disclosure, a semiconductor device is provided. The semiconductor device may include a stack structure including conductor layers and dielectric layers stacked alternately along a first direction. The semiconductor device may include at least one semiconductor structure penetrating through the stack structure. The semiconductor structure may include a capacitor structure, a first transistor structure, and a second transistor structure extending in the stack structure along the first direction. The second transistor structure, the first transistor structure, and the capacitor structure in a same semiconductor structure may be arranged and connected sequentially along the first direction.

In some implementations, the capacitor structure may include a plurality of memory capacitors that are arranged spaced apart along the first direction.

In some implementations, the memory capacitors may each include a first electrode and a dielectric layer. In some implementations, the dielectric layer may be connected with a first conductor layer and is disposed between the first electrode and the first conductor layer.

In some implementations, along a radial direction of the capacitor structure, the first electrode may include a plurality of layers of sub-electrodes. In some implementations, the radial direction may intersect the first direction.

In some implementations, the first transistor structure may include a first gate structure connected with a first face of the capacitor structure along the first direction. In some implementations, the first transistor structure may include a first isolation structure connected with a first side of the first gate structure along the first direction. In some implementations, the first transistor structure may include a first spacing structure surrounding the first gate structure and the first isolation structure. In some implementations, the first transistor structure may include a first drain structure connected with a first end of the first isolation structure along the first direction and a first surface of the first spacing structure along the first direction. In some implementations, the first transistor structure may include a first channel structure surrounding the first spacing structure and the first drain structure. In some implementations, the first channel structure may be connected with a second conductor layer. In some implementations, part of the second conductor layer connected with the first channel structure may serve as a first source structure of the first transistor structure.

In some implementations, a size of the first channel structure along a second direction may be greater than a size of the capacitor structure along the first direction. In some implementations, the second direction may intersect the first direction.

In some implementations, a size of the first gate structure in the first direction may be greater than a size of the second conductor layer connected with the first gate structure in the first direction.

In some implementations, the first isolation structure may include an isolation trench structure and a dielectric material layer within the isolation trench structure. In some implementations, a size of the first drain structure along the second direction may be greater than a size of the dielectric material layer along the second direction.

In some implementations, the second transistor structure may include a second source structure connected with a first end face of the first drain structure along the first direction. In some implementations, the second transistor structure may include a second isolation structure connected with a first side edge of the second source structure along the first direction. In some implementations, the second transistor structure may include a second drain structure connected with a first sidewall of the second isolation structure along the first direction. In some implementations, the second transistor structure may include a second channel structure surrounding the second source structure, the second isolation structure and the second drain structure. In some implementations, the second transistor structure may include a second spacing structure surrounding the second channel structure. In some implementations, the second spacing structure may be connected with a third conductor layer. In some implementations, part of the third conductor layer connected with the second spacing structure may serve as a second gate structure of the second transistor structure.

In some implementations, an orthographic projection of the second spacing structure on the stack structure may be within a region surrounded by an outer side face of the first channel structure. In some implementations, an outer side face of the second spacing structure may be spaced from the outer side face of the first channel structure by a preset distance.

In some implementations, a material of the dielectric layer may include one or more of a ferroelectric material and an anti-ferroelectric material.

In some implementations, a material of sub-electrodes in the layers of sub-electrodes may include one or more of titanium nitride and polysilicon.

In some implementations, the semiconductor device may include a core area and a connection area that are arranged along a second direction. In some implementations, the semiconductor structure may be located in the core area. In some implementations, the second direction may intersect the first direction. In some implementations, the connection area may include a plurality of first leading-out structures extending in the stack structure along the first direction. In some implementations, the plurality of first leading-out structures may be spaced apart in the second direction. In some implementations, each of the first leading-out structures may be connected separately with the conductive layers having a preset depth.

In some implementations, each of the first leading-out structures may include a conductive contact extending along the first direction. In some implementations, each of the first leading-out structures may include an insulation barrier layer surrounding the conductive contact.

In some implementations, the semiconductor device may further include third leading-out structures extending in the protective layer along the first direction and connected with the second drain structure in the second transistor structure.

In some implementations, the semiconductor device may include a core area and a staircase area that are arranged along a second direction. In some implementations, the semiconductor structure may be located in the core area. In some implementations, the second direction may intersect the first direction. In some implementations, the staircase area may include a plurality of staircase structures. In some implementations, lengths of the plurality of staircase structures along the second direction may be in gradual variation. In some implementations, the staircase structures may each include at least one of the conductor layers and at least one of the dielectric layers. In some implementations, the staircase area may include a plurality of second leading-out structures extending along the first direction. In some implementations, the plurality of second leading-out structures may be arranged spaced apart in the second direction. In some implementations, each of the second leading-out structures may be connected separately with the conductive layers having a preset depth in the staircase structure.

In some implementations, the semiconductor device may further include a protective layer covering a face of the stack structure along the first direction and a preset region within the staircase area. In some implementations, the preset region may include a region within the staircase area other than the staircase structures and the second leading-out structures. In some implementations, the semiconductor device may further include third leading-out structures extending in the protective layer along the first direction and connected with the second drain structure in the second transistor structure.

According to another aspect of the present disclosure, a method of fabricating a semiconductor device is provided. The method may include forming a stack structure including conductor layers and dielectric layers stacked alternately. The method may include forming at least one semiconductor structure penetrating through the stack structure. The semiconductor structure may include a capacitor structure, a first transistor structure, and a second transistor structure that extend in the stack structure along a first direction. In some implementations, the second transistor structure, the first transistor structure, and the capacitor structure in a same semiconductor structure are arranged and connected sequentially along the first direction.

In some implementations, the forming the at least one semiconductor structure penetrating through the stack structure may include forming the capacitor structure extending along the first direction in the stack structure. In some implementations, the forming the at least one semiconductor structure penetrating through the stack structure may include forming the first transistor structure extending along the first direction and in contact and connected with a first face of the capacitor structure along the first direction in the stack structure. In some implementations, the forming the at least one semiconductor structure penetrating through the stack structure may include forming the second transistor structure extending along the first direction and in contact and connected with a face of the first transistor structure away from the capacitor structure along the first direction in the stack structure.

According to a further aspect of the present disclosure, a memory system is provided. The memory system may include a three-dimensional memory. The three-dimensional memory may include a stack structure. The stack structure may include conductor layers and dielectric layers stacked alternately along a first direction. The three-dimensional memory may include at least one semiconductor structure penetrating through the stack structure. The semiconductor structure may include a capacitor structure, a first transistor structure, and a second transistor structure extending in the stack structure along the first direction. The second transistor structure, the first transistor structure, and the capacitor structure in a same semiconductor structure may be arranged and connected sequentially along the first direction. The memory system may include a controller coupled to the three-dimensional memory and configured to control the three-dimensional memory to store data.

Examples of the present disclosure provide a semiconductor device and a method of fabricating a semiconductor device, and a memory system. A semiconductor structure in the semiconductor device may include a capacitor structure, a first transistor structure, and a second transistor structure that extends in a stack structure along a first direction. The second transistor structure, the first transistor structure, and the capacitor structure in a same semiconductor structure may be arranged and connected sequentially along the first direction. This may achieve a vertical configuration of transistor structures and capacitor structures in the semiconductor structure, which increases the density of memory capacitors, and increases the storage density of the semiconductor device.

### BRIEF DESCRIPTION OF THE DRAWINGS

FIG. 1 is an equivalent circuit diagram of one memory cell in a semiconductor device provided by some examples.

FIGS. 2 to 28 are schematic structural diagram at multiple stages of a semiconductor device provided by examples of the present disclosure.

FIG. 29 is a schematic structural diagram of a semiconductor structure in a semiconductor device provided by examples of the present disclosure.

FIG. 30 is an equivalent circuit diagram of one memory cell in a semiconductor device provided by examples of the present disclosure.

FIG. 31 is a flow diagram of a fabrication method of a semiconductor device provided by examples of the present disclosure.

FIG. 32 is a schematic structural diagram of a memory system provided by examples of the present disclosure.

### DETAILED DESCRIPTION

The technical solutions in examples of the present disclosure will be described below clearly and completely in conjunction with the drawings in the examples of the present disclosure. The examples described herein are only part of, but not all of, the examples contemplated by the present disclosure. All other examples obtained by those skilled in the art based on the examples in the present disclosure without creative work shall fall in the scope of protection of the present disclosure.

In the description of the present disclosure, it should be understood that the terms “first” and “second” are only for the purpose of description, and cannot be construed as indicating or implying relative importance or implicitly indicating the number of indicated technical features. Thus, features defined by “first” and “second” may explicitly or implicitly include one or more of the features. In the description of the present disclosure, “a plurality of” means two or more, unless otherwise defined expressly and specifically.

In the description of the present disclosure, “at least one of A, B and C” and “at least one of A, B or C” have the same meaning, both including the following combinations of A, B and C: A alone, B along, C alone, a combination of A and B, a combination of A and C, a combination of B and C, and a combination of A, B and C. “A and/or B” includes the following three combinations: A alone, B alone, and a combination of A and B.

In the description of the present disclosure, It should be noted that unless otherwise specified and defined expressly, the terms “mounted”, “linked” and “connected” should be understood broadly, which, for example, may be fixed connection, detachable connection, or integrated connection; may be either mechanical connection or electrical connection or may be intercommunication; may be either direct connection or indirect connection through intermediate media, and may be connection inside two elements or an interaction relationship of two elements.

Those of ordinary skill in the art may understand the specific meanings of the above terms in the present disclosure according to specific conditions.

In the present disclosure, unless otherwise specified and defined expressly, a first feature being “over” or “under” a second feature may include the first feature being in direct contact with the second feature, and may also include the first feature being in contact with the second feature through another feature therebetween, instead of being in direct contact with the second feature. Moreover, the first feature being “over”, “above” and “on” the second feature includes the first feature being right above and above the second feature, or only means that the level of the first feature is higher than that of the second feature. The first feature being “under”, “below” and “beneath” the second feature includes the first feature being just below and below the second feature, or only means that the level of the first feature is less than that of the second feature.

Example implementations are described herein with reference to a cross-sectional view and/or a planar view used as idealized example drawings. In the drawings, thicknesses of layer and region are exaggerated for clarity. Thus, changes in shapes relative to the drawings caused by, for example, manufacturing technology and/or tolerance, may be contemplated. Therefore, the example implementations should not be interpreted as being limited to the shapes of regions shown herein, but rather include shape deviations caused by, for example, manufacturing. For example, an etching region shown as a rectangle will typically have a curved feature. Therefore, the regions shown in the drawings are essentially schematic, and their shapes are neither intended to show actual shapes of regions of an apparatus, nor intended to limit the scope of the example implementations.

As used herein, the term “substrate” refers to a material onto which subsequent material layers may be added. The substrate itself can be patterned. Materials added onto the substrate can be patterned or can remain unpatterned. Furthermore, the substrate may include a variety of semiconductor materials, such as silicon, germanium, gallium arsenide, indium phosphide, etc. Alternatively, the substrate can be made from an electrically non-conductive material, such as glass, plastic, or sapphire wafers, etc.

Some examples of the present disclosure provide an electronic apparatus which may include a memory system configured to achieve data storage as described below, and may also include at least one of a central processing unit (CPU) and a cache, etc. In an example, the electronic apparatus may be any one of a cellphone, a desktop computer, a tablet computer, a notebook computer, a server, a vehicle apparatus, a wearable apparatus (e.g., a smart watch, a smart bracelet, smart glasses, etc.), a mobile power supply, a gaming machine, a digital multimedia player, etc.

As used in the present disclosure, the term “layer” refers to a material portion including a region with a thickness. A layer has a top side and a bottom side, where the bottom side of the layer is relatively close to the substrate while the top side is relatively away from the substrate. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layers thereon, there above, and/or there below. A layer can include multiple layers. For example, an interconnection layer can include one or more gate line layers and contact layers in which contacts, interconnection lines and one or more dielectric layers are formed.

It is to be noted that the diagrams provided in the examples of the present disclosure only schematically illustrate the basic concept of the present disclosure. The diagrams only show components related to the present disclosure, instead of being drawn according to the number, shapes and sizes of components in practical implementation. In practical implementation, the shape, number and scale of various components may be changed freely, and the layout forms of the components may also be more complex.

The details below provide many different implementations or examples to achieve different structures of the present disclosure. In order to simplify the present disclosure, components and settings of specific examples are described below. Of course, they are merely examples, and are not intended to limit the present disclosure. In addition, the present disclosure may repeat the reference numerals and/or reference letters in different examples, and such repetitions are for the purposes of simplification and clarity, and do not indicate in themselves the relationships between various implementations and/or settings as discussed. In addition, the present disclosure provides examples of various specific processes and materials. However, those of ordinary skill in the art may realize the disclosure of other processes and/or use of other materials.

Transistors are used as a switching or selection device in a memory cell of some memory devices (e.g., a DRAM, a phase-change memory (PCM), a ferroelectric DRAM (Fe RAM), etc.). However, a planar transistor commonly used in the memory cell typically has a horizontal structure in which a word line is buried in a substrate and a bit line is above the substrate. A memory cell of a semiconductor device may be a 1T1C cell consisting of one transistor and one capacitor. It is to be understood that the memory cell may be of any suitable XTYC configuration, such as a 1T2C cell, a 1T3C cell, a 2T1C cell, a 3T1C cell, a 2T3C cell, etc., where X and Y are positive integers, T is an abbreviation for a transistor, and C is an abbreviation for a capacitor.

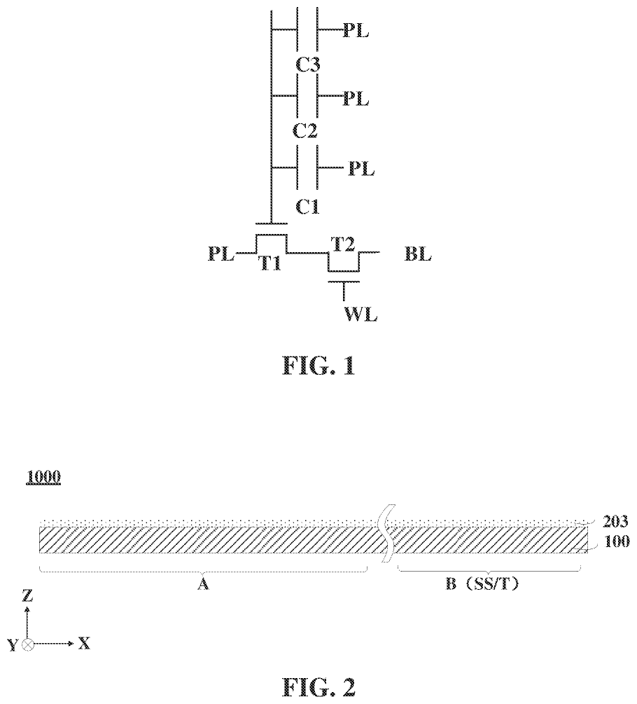

In some implementations, referring to FIG. 1, the memory cell includes a 2T3C configuration, in which 2 transistors are placed side by side horizontally, and 3 memory capacitors C are placed side by side vertically. A first electrode of the first transistor T1 is connected with a plate line (PL). A second electrode of the first transistor T1 is connected with a first electrode of the second transistor T2. A second electrode of the second transistor T2 is connected with a bit line (BL). A gate of the first transistor T1 is connected with first electrode plates of the first memory capacitor C1, the second memory capacitor C2 and the third memory capacitor C3. A gate of the second transistor T2 is connected with a word line (WL). Furthermore, second electrode plates of the three memory capacitors are connected separately with the plate line PL. The density of the plurality of memory capacitors arranged vertically on a horizontal plane will reduce the density of the 2T3C.

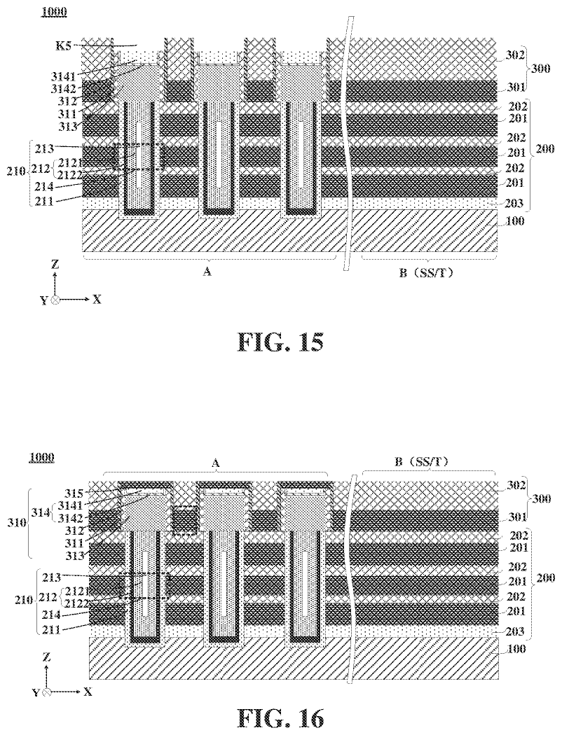

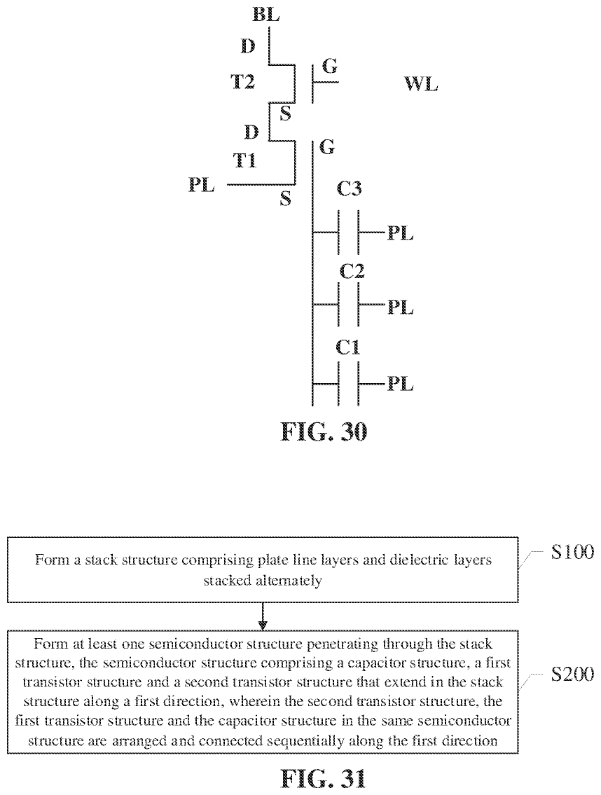

In order to improve the above problem, referring to FIGS. 2 to 32, examples of the present disclosure provide a semiconductor device 1000 and a fabrication method thereof, and a memory system. A semiconductor structure 20 formed by the present disclosure may include a capacitor structure 210, a first transistor structure 310, and a second transistor structure 410 extending in a stack structure 10 along a stacking direction (Z direction). The second transistor structure 410, the first transistor structure 310, and the capacitor structure 210 in the same semiconductor structure 20 may be arranged and connected sequentially along the first direction Z. As such, vertical arrangement of a plurality of transistor structures and a plurality of memory capacitors 214 may be achieved, which may reduce footprint of the transistor structures and the memory capacitors 214. This, in turn, may improve storage density and miniaturization of the present three-dimensional memory device. A design of vertically-arranged transistors also simplifies arrangement of an interconnection structure (e.g., a word line and a bit line) coupled to a memory cell, thereby reducing the limitations on spacing of at least one of the word lines or the bit line. Moreover, the impact of the vertically-arranged memory capacitors 214 leading-out of the vertically-arranged transistor structures may be reduced, thereby reducing manufacturing complexity and improving product yield.

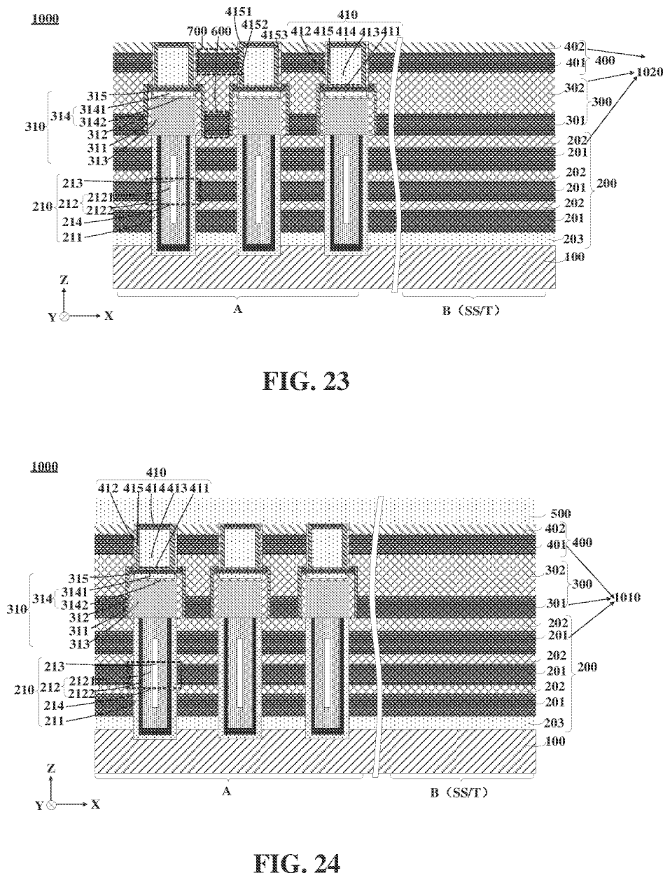

Referring to FIG. 23, a schematic structural diagram of a semiconductor device provided by examples of the present disclosure is shown. FIGS. 2 to 22 are schematic structural diagrams at various stages of forming the semiconductor device as shown in FIG. 23. The semiconductor device may include a stack structure 10 including conductor layers and dielectric layers stacked alternately along a first direction Z. The semiconductor device may include at least one semiconductor structure 20 penetrating through the stack structure 10. The semiconductor structure 20 may include a capacitor structure 210, a first transistor structure 310, and a second transistor structure 410 extending in the stack structure 10 along the first direction Z (Z direction). In some implementations, the second transistor structure 410, the first transistor structure 310, and the capacitor structure 210 in the same semiconductor structure 20 are arranged and connected sequentially along the first direction Z.

In some examples, the stack structure 10 as shown in FIGS. 2 to 28 may include the dielectric layers and the conductor layers that are stacked alternately in the first direction Z and extend along a second direction and a third direction. The second direction intersects the first direction Z, and the third direction intersects the first direction Z and the second direction. Here, the second direction intersecting the first direction Z may be interpreted as having an angle between the second direction and the first direction Z being less than or equal to 90 degrees. The third direction intersecting the first direction Z and the second direction may be interpreted as having an angle between the third direction. A plane where the first direction Z and the second direction are located may be less than or equal to 90 degrees. In some examples of the present disclosure, the angle between the second direction and the first direction Z is equal to 90 degrees, and the angle between the third direction and the plane where the first direction Z and the second direction are located is equal to 90 degrees.

In some examples, the first direction Z may be interpreted as a Z axis direction as shown in FIGS. 2-29. The second direction may be interpreted as an X axis direction as shown in FIGS. 2-29. The third direction may be interpreted as a Y axis direction as shown in FIGS. 2-29.

In an example, referring to FIGS. 2 to 28, the stack structure 10 may include a first stack layer 200, a second stack layer 300, and a third stack layer 400 stacked sequentially along the first direction Z. The first stack layer 200 may include first conductor layers 201 and first dielectric layers 202 stacked alternately along the first direction Z. The second stack layer 300 may include second conductor layers 301 and second dielectric layers 302 stacked alternately along the first direction Z. The third stack layer 400 may include third conductor layers 401 and third dielectric layers 402 stacked alternately along the first direction Z. Of course, the first stack layer 200 may further include a fourth dielectric layer 203 between a substrate 100 and the first conductor layer 201.

In an example, a substrate 100 that extends in the second direction X and the third direction Y to form a stack plane on which the stack layers are formed. As an example, the substrate 100 may be selected according to use-case scenarios. For example, the material of the substrate 100 may include a silicon substrate, a germanium (Ge) substrate, a silicon germanium (SiGe) substrate, a Silicon-on-Insulator (SOI) substrate, or a (Germanium-on-Insulator) GOI substrate, etc. In this example, the substrate 100 includes a monocrystalline silicon substrate.

In some examples, the substrate 100 may be a semiconductor substrate. For example, the substrate may include a monocrystalline silicon (Si) substrate, a monocrystalline germanium (Ge) substrate, a silicon-on-insulator (SOI) substrate, or a germanium on insulator (GOI) substrate, or the like. In some examples, the substrate 100 may be formed after ion doping. In an example, the substrate may be a P-type doped substrate, and may also be an N-type doped substrate. A suitable material may be selected as the substrate according to the use-case scenario, to which the present disclosure imposes no specific limitation. Of course, in other examples, the material of the substrate may also include a semiconductor or a compound including other elements. For example, the substrate may be a gallium arsenide (GaAs) substrate, an indium phosphide (InP) substrate, or a silicon carbide (SiC) substrate, or the like. In some other examples, the substrate is made of a non-conductive material which may include, for example, glass, plastic, or sapphire wafers, etc.

In some examples, a deposition method is selected according to use-case scenario(s) to form the stack structure 10 having a multi-layer structure on the stack plane. The number of the stack layers in the stack structure 10 depicted in FIGS. 2 to 23 is provided by way of example and not limitation. For example, the number of the first dielectric layers 202 and the first conductor layers 201 in the first stack layer 200 may include 32 layers, 64 layers, 96 layers, 128 layers, etc. In an example, the number of the dielectric layers and the conductor layers included in different stack layers in the stack structure 10 may be set according to use-case scenario. That is, the number of layers of the stack structure 10 is not limited.

In some examples, the first dielectric layer 202 to the fourth dielectric layer 203 may all include an insulation material, e.g., such as one or more of silicon nitride, silicon oxide, and/or aluminum oxide. Here, silicon oxide refers to a silicon-oxygen compound, e.g., such as SixOy. Silicon nitride refers to a nitrogen-silicon compound, e.g., such as SixNy. The first conductor layer 201 to the third conductor layer 401 may include, e.g., one or more of poly-Si (p-Si), titanium nitride (TiN), titanium (Ti), gold (Au), tungsten (W), molybdenum (Mo), indium-tin-oxide (ITO), aluminum (Al), copper (Cu), ruthenium (Ru), silver (Ag), and other conductive materials.

It is to be noted that the conductor layers and the dielectric layers have different etching selectivity, and a deposition method of the conductor layers and the dielectric layers may employ, but is not limited to, chemical vapor deposition (CVD), physical vapor deposition (PVD), plasma-enhanced CVD (PECVD), sputtering, metal-organic chemical vapor deposition (MOCVD), and atomic layer deposition (ALD), etc.

In some examples, the semiconductor device 1000 may further include the at least one semiconductor structure 20 penetrating through the stack structure 10. In an example, with continued reference to FIG. 23, the semiconductor device 1000 is provided with three semiconductor structures 20 penetrating through the stack structure 10. The same semiconductor structure 20 may include one capacitor structure 210, one first transistor structure 310 and one second transistor structure 410 extending in the stack structure 10 along the first direction Z, where the second transistor structure 410, the first transistor structure 310 and the capacitor structure 210 in the same semiconductor structure 20 are arranged and connected sequentially along the first direction Z.

In some examples, the capacitor structure 210 may include a plurality of memory capacitors 214 that are spaced apart along the first direction Z.

In some examples, the same capacitor structure 210 corresponds to the plurality of memory capacitors 214 that are arranged along a stacking direction, e.g., the first direction Z. In an example, with continued reference to FIG. 23, one capacitor structure 210 of the same semiconductor structure 20 may include three memory capacitors 214.

The number of the semiconductor structures 20 in the semiconductor device depicted in FIG. 23 is provided by way of example and not limitation. Other numbers of semiconductor structures 20 may be included without departing from the scope of the present disclosure. Moreover, the numbers of the transistor structures and the capacitor structures 210 arranged and connected along the first direction Z depicted in FIG. 23 are only an example as well. For example, the number of the semiconductor structures 20 in the semiconductor device may include 1, 2, 3, 4, 5, etc. The number of the memory capacitors 214 included in the capacitor structure 210 in the same semiconductor structure 20 may include 1, 2, 3, 4, 5, etc. The number of transistors included in the capacitor structure 210 in the same semiconductor structure 20 may include, e.g., 2, 3, 4, 5, etc. The transistor structures and the capacitor structures 210 arranged and connected along the first direction Z in the same semiconductor structure 20 may be of any suitable XTYC configuration, e.g., such as a 2T1C structure, a 2T2C structure, a 2T3C structure, a 2T4C structure, a 2T5C structure, a 3TIC structure, a 3T2C structure, etc., where X is a positive integer greater than 1, Y is a positive integer, T represents the transistor structure, and C represents the capacitor structure 210. The plurality of memory capacitors 214, the first transistor structure 310, and the second transistor structure 410 corresponding to the same semiconductor structure 20 may constitute one memory cell as described above.

In some examples, the memory capacitor 214 may include a first electrode 212 and a dielectric layer 211. The dielectric layer 211 may be connected with the first conductor layer 201, and may be disposed between the first electrode 212 and the first conductor layer 201.

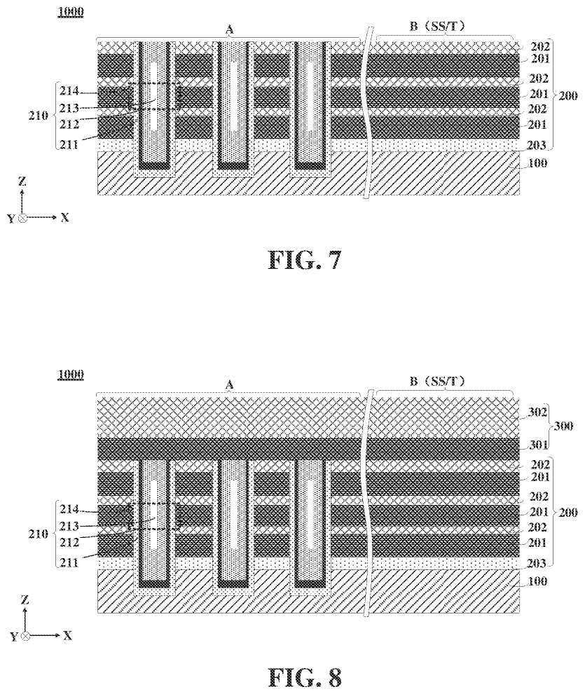

In some examples, referring to FIGS. 7 to 23, the capacitor structure 210 may include a dielectric layer 211 and a first electrode 212 disposed sequentially from outside to inside. The dielectric layer 211 is used for enabling the semiconductor device 1000 to achieve storage function. The dielectric layer 211 is located between the plurality of first conductor layers 201 and the first electrode 212. The dielectric layer 211 is connected with the corresponding first conductor layer 201 having a first preset depth in the stack structure 10 along the first direction Z. The dielectric layer 211 and the first electrode 212 both extend along the first direction Z. Part of each of the dielectric layer 211 and the first electrode 212 opposite to the first conductor layer 201 forms one memory capacitor 214 with the first conductor layer 201. Part of each of the first conductor layers 201 surrounding the dielectric layer 211 constitutes a second electrode of the memory capacitor 214.

In an example, the number of the first conductor layers 201 is multiple, and part of, each first conductor layer 201 surrounding the dielectric layer 211. Part of the dielectric layer 211 and the first electrode 212 opposite to the first conductor layer 201 form one memory capacitor 214. The plurality of memory capacitors 214 corresponding to the same semiconductor structure 20 share the first electrode 212 and the dielectric layer 211 that both extend along the first direction Z, which may, in turn, enable the plurality of memory capacitors 214 to be arranged along the first direction Z.

In some examples, a material of the dielectric layer 211 includes one or more of a ferroelectric material or an anti-ferroelectric material.

In some examples, the material of the dielectric layer 211 may include multiple materials as long as the dielectric layer 211 can achieve the desired storage effect, and the examples of the present disclosure impose no limitation thereto. For example, the dielectric layer 211 may be a ferroelectric layer, and the ferroelectric layer may include a high-k (e.g., high dielectric constant) dielectric material. The high-k dielectric material may include a transition metal oxide, e.g., such as at least one of hafnium oxide (HfO₂), aluminum oxide (Al₂O₃), zirconium oxide (ZrO₂), titanium oxide (TiO₂), niobium oxide (Nb₂O₅), tantalum oxide (Ta₂O₅), tungsten oxide (WO₃), molybdenum oxide (MO₃), vanadium oxide (V₂O₃), lanthanum oxide (La₂O₃), or any combination thereof. In some implementations, the high k dielectric material may be also doped. For example, the dielectric layer 211 may include HfO₂ doped with silicon (Si), yttrium (Y), gadolinium (Gd), lanthanum (La), zirconium (Zr), or aluminum (Al) or any combination thereof.

In an example, the dielectric layer 211 may be a ferroelectric layer. Part of the first conductor layer 201 surrounding the dielectric layer 211, part of the dielectric layer 211, and the first electrode 212 opposite to the first conductor layer 201 form a ferroelectric capacitor, e.g., one of the above memory capacitors 214. At this point, a three-dimensional memory 320 that includes the semiconductor device 1000 may be a ferroelectric memory. The ferroelectric memory has the advantages of nonvolatility, high rate, low-power consumption, and the like. The ferroelectric memory may be a ferroelectric random access memory (FeRAM) or a ferroelectric field-effect-transistor (FeFET) memory, just to name a few.

In some examples, the first electrode 212 may include a plurality of layers of sub-electrodes along a radial direction (an X direction) of the capacitor structure 210, and the radial direction intersects the first direction Z.

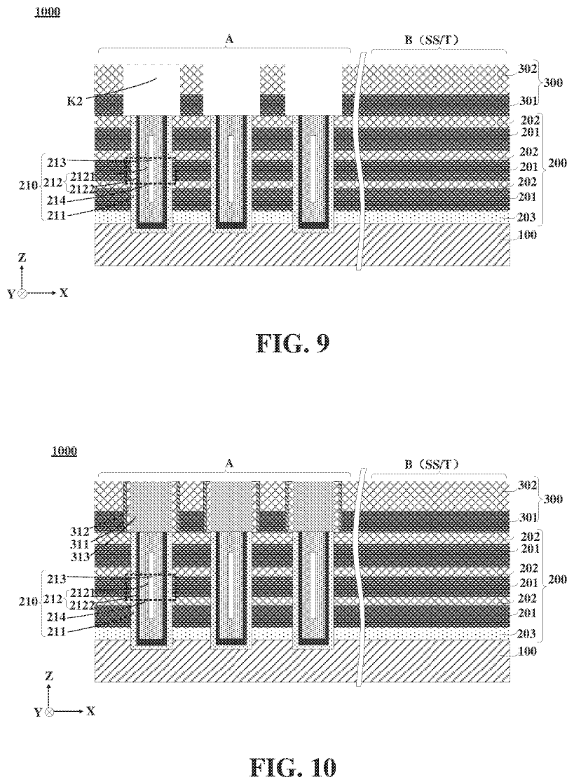

In some examples, the first electrode 212 may include at least one layer of sub-electrode along the radial direction of the capacitor structure 210. For example, referring to FIGS. 9 to 23, along the radial direction of the capacitor structure 210, the first electrode 212 may include a first sub-electrode 2121 and a second sub-electrode 2122 surrounding the first sub-electrode 2121. A material of the plurality of layers of sub-electrodes may employ a conductive material, e.g., such as one or more of conductive materials such as TiN (titanium nitride), TaN (tantalum nitride), Ti (titanium), Au (gold), W (tungsten), Mo (molybdenum), In—Ti—O (ITO, indium tin oxide), Al (aluminum), Cu (copper), Ru (ruthenium), Ag (silver), Pt (platinum), polysilicon, etc.

It should be noted that materials of the plurality of layers of sub-electrodes such as the first sub-electrode 2121 and the second sub-electrode 2122 may be the same or different. When the materials of the plurality of layers of sub-electrodes are the same, their respective densities may be different. In an example, the material of the sub-electrode includes one or more of titanium nitride (TiN) and polysilicon.

In some examples, with continued reference to FIGS. 7 and 23, the capacitor structure 210 may include a support pillar 213 extending along the first direction Z. The second sub-electrode 2122 is disposed around the support pillar 213, the support pillar 213 may be in a cylinder shape, and the second sub-electrode 2122 surrounds the support pillar 213. In an example, the support pillar 213 may employ, for example, an insulation material that may include, for example, at least one of silicon oxide, silicon nitride, or silicon oxynitride. By disposing the support pillar 213, a support effect may be provided, as described below in connection with FIGS. 24 to 29.

In some examples, the first transistor structure 310 may include first gate structure 313 connected with a first face 220 of the capacitor structure 210 along the first direction Z.

In some examples, referring to FIGS. 16 to 29, the first transistor structure 310 may include the first gate structure 313. The capacitor structure 210 may include the first face 220 (e.g., an upper surface or a top face) away from the substrate 100 along the first direction Z, and a second face (e.g., a lower surface or a bottom face, not shown in the figures) close to the substrate 100 along the first direction Z. The first gate structure 313 may include a first side 3139 (e.g., an upper surface or a top face) away from the substrate 100 or the capacitor structure 210 along the first direction Z, and a second side 3130 (e.g., a lower surface or a bottom face) close to the substrate 100 or the capacitor structure 210 along the first direction Z. The first face 220 (e.g., the upper surface or the top face) of the capacitor structure 210 along the first direction Z as shown in FIGS. 7 to 29 is in contact and connected with the second side 3130 (e.g., the lower surface or the bottom face) of the first gate structure 313 along the first direction Z. The second face (e.g., the lower surface or the bottom face) of the capacitor structure 210 along the first direction Z as shown in FIGS. 7 to 29 is in contact and connected with the substrate 100. It is noted that a size of the first gate structure 313 along the second direction X may be greater than or equal to a size of the capacitor structure 210 along the second direction X. A material of the first gate structure 313 includes a conductive material, including, but not limited to, polysilicon, or metal silicide, such as silicide of a metal selected from cobalt (Co), nickel (Ni), hafnium (Hf), platinum (Pt), W, and titanium (Ti).

A first isolation structure 314 may be connected with the first side 3139 of the first gate structure 313 along the first direction Z.

In some examples, with continued reference to FIGS. 16 to 29, the first transistor structure 310 may further include the first isolation structure 314. The first isolation structure 314 is located on a side of the capacitor structure 210 away from the substrate as shown in FIGS. 7 to 29. The first isolation structure 314 may include a first end 3149 (e.g., an upper surface or a top face) away from the substrate 100 or the capacitor structure 210 along the first direction Z, and a second end 3140 (e.g., a lower surface or a bottom face) close to the substrate 100 or the capacitor structure 210 along the first direction Z. The second side 3130 (e.g., the lower surface or the bottom face) of the first gate structure 313 along the first direction Z is in contact and connected with the first face 220 (e.g., the upper surface or the bottom face) of the capacitor structure 210 along the first direction Z. The first side 3139 (e.g., the upper surface or the top face) of the first gate structure 313 along the first direction Z is in contact and connected with the second end 3140 (e.g., the lower surface or the bottom face) of the first isolation structure 314 along the first direction Z. It is noted that a size of the first isolation structure 314 along the second direction X may be greater than or equal to the size of the first gate structure 313 along the second direction X. A material of the first isolation structure 314 may employ an insulation material that may include at least one of silicon oxide, silicon nitride, or silicon oxynitride.

A first spacing structure 312 may surround the first gate structure 313 and the first isolation structure 314.

In some examples, with continued reference to FIGS. 16 to 29, the first transistor structure 310 may further include the first spacing structure 312. The first spacing structure 312 is located on the side of the capacitor structure 210 away from the substrate as shown in FIGS. 7 to 29; and in the second direction X, the first spacing structure 312 is disposed around the first gate structure 313 and the first isolation structure 314. That is to say, the first spacing structure 312 may include a first cavity Q1 such that the first spacing structure 312 is a hollow pillar-shaped structure. The hollow pillar-shaped first spacing structure 312 may include two portions disposed oppositely along the second direction X, the two portions extend along the first direction Z, and the first gate structure 313 and the first isolation structure 314 are located within the first cavity Q1 of the first spacing structure 312. That is, the first gate structure 313 and the first isolation structure 314 are located between the two portions of the hollow pillar-shaped first spacing structure 312. It should be noted that a size of the first gate structure 313 along the second direction X may be greater than or equal to a size of the capacitor structure 210 along the second direction X. A material of the first spacing structure may employ an insulation material that may include, e.g., at least one of silicon oxide, silicon nitride, or silicon oxynitride.

A first drain structure 315 connected with the first end 3149 of the first isolation structure 314 along the first direction Z and a first surface 3129 of the first spacing structure 312 along the first direction Z.

In some examples, with continued reference to FIGS. 16 to 29, the first transistor structure 310 may further include the first drain structure 315. The drain structure 315 is located on a side of the first isolation structure 314 away from the substrate along the first direction Z as shown in FIGS. 7 to 29. The first spacing structure 312 may include the first surface 3129 (e.g., an upper surface or a top face) away from the substrate 100 or the capacitor structure 210 along the first direction Z, and a second surface 3120 (e.g., a lower surface or a bottom face) close to the substrate 100 or the capacitor structure 210 along the first direction Z. The first drain structure 315 may include a first end face 3159 (e.g., an upper surface or a top face) away from the substrate 100 or the capacitor structure 210 along the first direction Z. The first drain structure 315 may include a second end face 3150 (e.g., a lower surface or a bottom face) close to the substrate 100 or the capacitor structure 210 along the first direction Z. The second end 3140 (e.g., the lower surface or the bottom face) of the first isolation structure 314 along the first direction Z is in contact and connected with the first side 3139 (e.g., the upper surface or the top face) of the first gate structure 313 along the first direction Z. The first end 3149 (e.g., the upper surface or the top face) of the first isolation structure 314 along the first direction Z is in contact and connected with the second end face 3150 (e.g., the lower surface or the bottom face) of the first drain structure 315 along the first direction Z. Furthermore, the second end face 3150 (e.g., the lower surface or the bottom face) of the first drain structure 315 along the first direction Z is further connected with the first surface 3129 of the first spacing structure 312 along the first direction Z. It should be noted that a size of the first drain structure 315 along the second direction X may be greater than or equal to a sum of a size of the first isolation structure 314 along the second direction X and a size of the first spacing structure 312 along the second direction X. That is to say, projections of the first isolation structure 314 and the first spacing structure 312 along the second direction X are located within a range of a projection of the first drain structure 315 along the second direction X. A material of the first drain structure 315 may include a conductive material that may include monocrystalline silicon, polysilicon, etc.

A first channel structure 311 may surround the first spacing structure 312 and the first drain structure 315.

The first channel structure 311 is connected with the second conductor layer 301, and part of the second conductor layer 301 connected with the first channel structure 311 serves as a first source structure of the first transistor structure 310.

In some examples, referring to FIGS. 16 to 29, the first transistor structure 310 may further include the first channel structure 311. The first channel structure 311 is located on the side of the capacitor structure 210 away from the substrate as shown in FIGS. 7 to 29, and the first channel structure 311 is disposed around the first spacing structure 312 and the first drain structure 315. That is to say, the first channel structure 311 may include a second cavity Q2 such that the first channel structure 311 is a hollow pillar-shaped structure. The hollow pillar-shaped first channel structure 311 may include two portions disposed oppositely along the second direction X, the two portions extend along the first direction Z, and the first spacing structure 312 and the first drain structure 315 are located within the second cavity Q2 of the first channel structure 311. That is, the first spacing structure 312 and the first drain structure 315 are located between the two portions of the hollow pillar-shaped first channel structure 311. The first channel structure 311 is further connected with the second conductor layer 301 having a second preset depth in the stack structure 10 along the first direction Z. As shown in FIGS. 16 to 29, the plurality of first conductor layers 201 and the plurality of second conductor layers 301 are disposed sequentially in a direction along the first direction Z and away from the substrate. The second preset depth is less than the first preset depth. That is, referring to FIGS. 16 to 29, any one of the second conductor layers 301 is located above any one of the first conductor layers 201 along the first direction Z.

In some examples, the first channel structure 311 may employ a conductive material that may include monocrystalline silicon, polysilicon, etc., such as N-type doped polysilicon, and P-type doped polysilicon.

In some examples, a size CD1 of the first channel structure 311 along the second direction X may be greater than a size CD2 of the capacitor structure 210 along the first direction Z, and the second direction X intersects the first direction Z.

In some examples, as shown in FIG. 12, the size CD1 of the first channel structure 311 along the second direction X is greater than the size CD2 of the capacitor structure 210 along the first direction Z, which can ensure that there is a certain safe distance between the first channel structure 311 and the dielectric layer 211 of each of the memory capacitors 214 in the capacitor structure 210, and avoid the phenomenon of electric breakdown.

In some examples, a size H1 of the first gate structure 313 in the first direction Z may be greater than a size H2 of the second conductor layer 301 connected with the first gate structure 313 in the first direction Z.

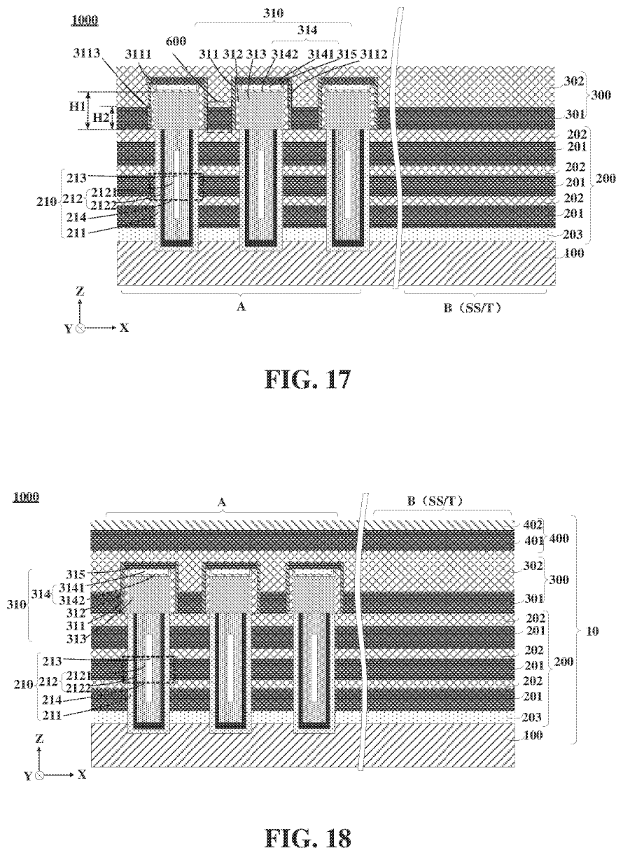

In some examples, as shown in FIG. 17, the size of the first gate structure 313 in the first direction Z is greater than the size of the second conductor layer 301 connected with the first gate structure 313 in the first direction Z. The first channel structure 311 may be divided into three portions along the first direction Z, and the first portion 4151 to the third portion 4153 are arranged sequentially in a direction approaching the capacitor structure 210 along the first direction Z. That is, the first portion 4151 is located above the second portion 4152 along the first direction Z, and the second portion 4152 is located above the third portion 4153 along the first direction Z. The first portion 4151 of the first channel structure 311 is connected with the first drain structure 315. As such, the first portion 4151 of the first channel structure 311 may serve as a portion of the first drain structure 315. The second portion 4152 of the first channel structure 311 is connected with the second dielectric layer 302. As such, certain fixed voltage may be applied to the first gate structure 313 connected with a plate line (PL) through the plate line such that during a store (write) operation, holes can be kept in the first channel structure 311, and hole leakage is reduced when voltage of the first gate structure 313 varies.

The third portion 4153 of the first channel structure 311 is connected with the first conductor layer 201. As shown in FIG. 17, the first conductor layer 201 may serve as a first source structure 600 jointly used by the two first transistor structures 310 in the adjacent semiconductor structures 20 arranged along the second direction X. That is, the two first transistor structures 310 in the adjacent semiconductor structures 20 arranged along the second direction X have a common source. For example, as shown in FIGS. 16 to 29, the illustrated leftmost first transistor structure 310 and the illustrated middle first transistor structure 310 have a common source, and the illustrated rightmost first transistor structure 310 and the illustrated middle first transistor structure 310 have a common source.

It should be noted that FIGS. 2 to 29 are part of a schematic structural diagram of a semiconductor device of the present disclosure. Therefore, as shown in FIGS. 16 to 29, except that the adjacent first transistors jointly use the first source structure, the first source structure in the semiconductor device may serve as a common source of all the first transistors in the semiconductor device.

In some examples, the first isolation structure 314 may include an isolation trench structure 3141 and a dielectric material layer 3142 within the isolation trench structure 3141, where the size of the first drain structure 315 along the second direction X is greater than a size of the dielectric material layer 3142 along the second direction X.

In some examples, as shown in FIGS. 14 to 29, the first isolation structure 314 may include the isolation trench structure 3141 and the dielectric material layer 3142, where the dielectric material layer 3142 is located within the isolation trench structure 3141, and the isolation trench structure 3141 and the dielectric material layer 3142 may both employ an insulation material. Here, the insulation material may include, e.g., at least one of silicon oxide, silicon nitride, or silicon oxynitride. For example, the isolation trench structure 3141 employs silicon nitride, and the dielectric material layer 3142 employs at least one of silicon oxide or silicon oxynitride.

In some examples, the second transistor structure 410 may include a second source structure 411 connected with the first end face 3159 of the first drain structure 315 along the first direction Z.

In some examples, referring to FIGS. 23 to 29, the second transistor structure 410 may include the second source structure 411. The second source structure 411 may include a first side edge 4119 (e.g., an upper surface or a top face) away from the substrate 100 along the first direction Z and a second side edge 4110 (e.g., a lower surface or a bottom face) close to the substrate 100 along the first direction Z. The second side edge 4110 (e.g., the lower surface or the bottom face) of the second source structure 411 along the first direction Z is in contact and connected with the first end face (e.g., the upper surface or the top face) of the first drain structure 315 in the first transistor structure 310 along the first direction Z as shown in FIGS. 16 to 29. It should be noted that a size of the second source structure 411 along the second direction X is less than the size of the first drain structure 315 along the second direction X. A material of the second source structure 411 may include a conductive material that may include monocrystalline silicon, polysilicon, etc.

A second isolation structure 413 may be connected with the first side edge 4119 of the second source structure 411 along the first direction Z.

In some examples, with continued reference to FIGS. 23 to 29, the second transistor structure 410 may further include the second isolation structure 413. The second isolation structure 413 may include a first sidewall 4139 (e.g., an upper surface or a top face) away from the substrate 100 along the first direction Z and a second sidewall 4130 (e.g., a lower surface or a bottom face) close to the substrate 100 along the first direction Z. The second isolation structure 413 is located on a side of the first transistor structure 310 away from the substrate 100 or the capacitor structure 210 as shown in FIGS. 16 to 29. The first side edge 4119 (e.g., the upper surface or the top face) of the second source structure 411 along the first direction Z is in contact and connected with the second sidewall 4130 (e.g., the lower surface or the bottom face) of the second isolation structure 413 along the first direction Z. It should be noted that a size of the second isolation structure 413 along the second direction X may be less than or equal to the size of the second source structure 411 along the second direction X. A material of the second isolation structure 413 may employ an insulation material that may include at least one of silicon oxide, silicon nitride, or silicon oxynitride.

A second drain structure 414 may be connected with the first sidewall 4139 of the second isolation structure 413 along the first direction Z.

In some examples, with continued reference to FIGS. 23 to 29, the second transistor structure 410 may further include the second drain structure 414. The second drain structure 414 may include a first end 4149 (e.g., an upper surface or a top face) away from the substrate 100 along the first direction Z. The second drain structure 414 may include a second end 4140 (e.g., a lower surface or a bottom face) close to the substrate 100 along the first direction Z. The second drain structure 414 is located on a side of the second isolation structure 413 away from the substrate along the first direction Z as shown in FIGS. 7 to 29. The first sidewall 4139 (e.g., the upper surface or the top face) of the second isolation structure 413 along the first direction Z is in contact and connected with the second end 4140 (e.g., the lower surface or the bottom face) of the second drain structure 414 along the first direction Z. It should be noted that a size of the second drain structure 414 along the second direction X may be less than or equal to the size of the second isolation structure 413 along the second direction X. A material of the second drain structure 414 may include a conductive material that may include monocrystalline silicon, polysilicon, etc.

A second channel structure 415 may surround the second source structure 411, the second isolation structure 413, and the second drain structure 414.

In some examples, referring to FIGS. 23 to 29, the second transistor structure 410 may further include the second channel structure 415. The second channel structure 415 is located on a side of the first transistor structure 310 away from the substrate as shown in FIGS. 7 to 29. The second channel structure 415 is disposed around the second source structure 411, the second isolation structure 413, and the second drain structure 414. That is to say, the second channel structure 415 may include a third cavity Q3 such that the second channel structure 415 is a hollow pillar-shaped structure. The hollow pillar-shaped second channel structure 415 may include two portions disposed oppositely along the second direction X, the two portions extend along the first direction Z. The second source structure 411, the second isolation structure 413, and the second drain structure 414 are located within the third cavity Q3 of the second channel structure 415. That is, the second source structure 411, the second isolation structure 413 and the second drain structure 414 are located between the two portions of the hollow pillar-shaped second channel structure 415. Moreover, a sum of sizes of a projection of the second source structure 411 along the first direction Z, a projection of the second isolation structure 413 along the first direction Z, and a projection of the second drain structure 414 along the first direction Z is within a range of a projection of the second channel structure 415 along the first direction Z. In some examples, the second channel structure 415 may employ a conductive material that may include monocrystalline silicon, polysilicon, etc., such as N-type doped polysilicon, and P-type doped polysilicon.

A second spacing structure 412 surrounding the second channel structure 415, where the second spacing structure 412 is connected with the third conductor layer 401, and part of the third conductor layer 401 connected with the second spacing structure 412 serves as a second gate structure of the second transistor structure 410.

In some examples, with continued reference to FIGS. 23 to 29, the second transistor structure 410 may further include the second spacing structure 412. The second spacing structure 412 is located on the side of the first transistor structure 310 away from the substrate as shown in FIGS. 7 to 29. The second spacing structure 412 is disposed around the second channel structure 415. That is to say, the second spacing structure 412 may include a fourth cavity Q4 such that the second spacing structure 412 is a hollow pillar-shaped structure. The hollow pillar-shaped second spacing structure 412 may include two portions disposed oppositely along the second direction X, the two portions extend along the first direction Z, and the second channel structure 415 is located within the fourth cavity Q4 of the second spacing structure 412. That is, the second channel structure 415 is located between the two portions of the hollow pillar-shaped second spacing structure 412. It is to be noted that a size of the second spacing structure 412 along the second direction X may be less than the size of the first drain structure 315 along the second direction X. The size of the second spacing structure 412 along the second direction X may be even less than the size of the first isolation structure 314 along the second direction X. A material of the second spacing structure 412 may employ an insulation material that may include at least one of silicon oxide, silicon nitride, or silicon oxynitride.

In some examples, the second spacing structure 412 is further connected with the third conductor layer 401 having a third preset depth in the stack structure 10 along the first direction Z. As shown in FIGS. 23 to 29, the plurality of first conductor layers 201, the plurality of second conductor layers 301, and the plurality of third conductor layers 401 are disposed sequentially in a direction along the first direction Z and away from the substrate. The third preset depth is less than the second preset depth, and the second preset depth is less than the first preset depth. That is, referring to FIGS. 23 to 29, any one of the third conductor layers 401 is located above any one of the second conductor layers 301 along the first direction Z.

In some examples, as shown in FIG. 23, the second channel structure 415 may be divided into three portions along the first direction Z. The first portion 4151 to the third portion 4153 are arranged sequentially in a direction approaching the first transistor structure 310 along the first direction Z. That is, the first portion 4151 is located above the second portion 4152 along the first direction Z, and the second portion 4152 is located above the third portion 4153 along the first direction Z. The first portion 4151 of the second channel structure 415 is connected with the second drain structure 414. As such, the first portion 4151 of the second channel structure 415 may serve as a portion of the second drain structure 414. The second portion 4152 of the second channel structure 415 is connected with the third dielectric layer 402. As such, when certain voltage is applied to the first gate structure 313 through a word line, the second channel structure 415 can be turned on to achieve select function. The third portion 4153 of the second channel structure 415 is connected with the third conductor layer 401. As shown in FIG. 23, the third conductor layer 401 may serve as a second gate structure 700 jointly used by the two second transistor structures 410 in the adjacent semiconductor structures 20 arranged along the second direction X. That is, the two second transistor structures 410 in the adjacent semiconductor structures 20 arranged along the second direction X have a common gate. For example, as shown in FIGS. 23 to 29, the illustrated leftmost second transistor structure 410 and the illustrated middle second transistor structure 410 have a common gate; and the illustrated rightmost second transistor structure 410 and the illustrated middle second transistor structure 410 have a common gate.

In some examples, an orthographic projection of the second spacing structure 412 on the stack structure 10 is within a region surrounded by an outer side face of the first channel structure 311, and an outer side face of the second spacing structure 412 is spaced from the outer side face of the first channel structure 311 by a preset distance.

In some examples, the orthographic projection of the second spacing structure 412 on the stack structure 10 is within the region surrounded by the outer side face of the first channel structure 311. That is, the size of the second spacing structure 412 along the second direction X is less than a spacing distance between the two portions constituting the first channel structure 311 along the second direction X. In addition, the outer side face of the second spacing structure 412 is spaced from the outer side face of the first channel structure 311 by the preset distance such that the size of the first channel structure 311 of the first transistor structure 310 along the second direction X is set to be a size of the second channel structure 415 of the second transistor structure 410 along the second direction X. As such, not only can the select rate of the second gate structure in the second transistor structure 410 be increased, but also the amount of stored holes of the first channel structure 311 in the first transistor structure 310 can be increased, which improves the storage capability of the semiconductor device.

In some examples, the semiconductor device may include a core area A and a connection area T that are arranged along the second direction X, where the semiconductor structure 20 is located in the core area A, the second direction X intersects the first direction Z. The connection area T may include a plurality of first leading-out structures 504 extending in the stack structure 10 along the first direction Z, where the plurality of first leading-out structures 504 are spaced apart in the second direction X. Each of the first leading-out structures 504 may be connected separately with the conductor layer having a preset depth.

In some examples, as shown in FIG. 26, the semiconductor device may include the core area A and the connection area T that are arranged along the second direction X. The plurality of semiconductor structures 20 in the above examples are located in the core area A, and the plurality of semiconductor structures 20 may be spaced apart in the core area A along the second direction X by the same spacing or different spacings. The connection area T may include the plurality of first leading-out structures 504. Here, the first leading-out structures 504 extend in the connection area T of the stack structure 10 along the first direction Z; the plurality of first leading-out structures 504 are spaced apart along the second direction X; and the plurality of first leading-out structures 504 may be spaced apart in the connection area T along the second direction X by the same spacing or different spacings. Each of the first leading-out structures 504 is connected separately with the plurality of first conductor layers 201, the plurality of second conductor layers 301 and the plurality of third conductor layers 401.

In some examples, the first leading-out structure 504 may include a conductive contact 541 extending along the first direction Z. In some examples, the first leading-out structure 504 may include an insulation barrier layer 542 surrounding the conductive contact 541.

In some examples, with continued reference to FIG. 26, the first leading-out structure 504 may include the conductive contact 541 extending along the first direction Z, and the insulation barrier layer 542 extending along the first direction Z, where the insulation barrier layer 542 is disposed around the conductive contact 541.

In some examples, the conductive contact 541 may employ a conductive material that may include, but is not limited to, a combination of one or more of Si, TiN, Ti (titanium), Au, W, Mo, ITO, Al, Cu, Ru, Ag, and other conductive materials. The insulation barrier layer 542 may employ an insulation material that may include, but is not limited to, a combination of one or more of silicon nitride, silicon oxide, or aluminum oxide.

In some examples, the semiconductor device may further include a protective layer 500 covering a face of the stack structure 10 along the first direction Z. In some examples, the semiconductor device may further include third leading-out structures 501 extending in the protective layer 500 along the first direction Z and connected with the second drain structure 414 in the second transistor structure 410.

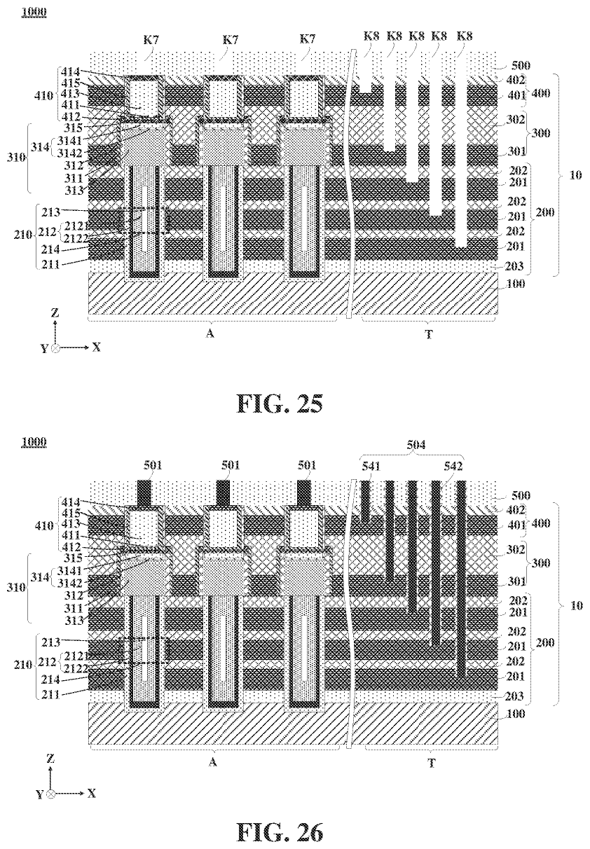

In some examples, referring to FIGS. 25 and 26, the protective layer 500 is disposed on a face of the stack structure 10 facing away from the substrate along the first direction Z. A material of the protective layer 500 may employ an insulation material that may include, but is not limited to, a combination of any one of more of silicon nitride, silicon oxide, or aluminum oxide. The semiconductor device may further include the third leading-out structures 501 each located on each of the second drain structures 414. That is, the plurality of third leading-out structures 501 are connected with a corresponding number of the second drain structures 414 in one-to-one correspondence.

In the examples of the present disclosure, referring to FIG. 26, the semiconductor device may include the third leading-out structures 501 extending along the first direction Z and connected with various second drain structures 414 of the core area A. The first leading-out structures 504 may extend along the first direction Z and connected with various conductor layers (e.g., including the plurality of first conductor layers 201, second conductor layers 301, and third conductor layers 401) of the connection area T. Each of the second drain structures 414 is connected with a bit line BL through one of third leading-out structures 501 such that each semiconductor structure 20 is connected with one bit line BL. Bottoms of the first channel structures 311 of the first transistor structures 310 in the plurality of semiconductor structures 20 are jointly connected to the second conductor layer 301 as the first source structure. That is, share one source layer, and the first leading-out structures 504 connected with the second conductor layer 301 may be connected with a plate line PL such that the plurality of first transistor structures 310 are connected to one plate line PL through the first leading-out structures 504 connected with the second conductor layer 301. The bottoms of the second channel structures 415 of the second transistor structures 410 in the plurality of semiconductor structures 20 are jointly connected to the third conductor layer 401 as the second gate structure, e.g., share one gate layer. The first leading-out structures 504 connected with the third conductor layer 401 may be connected with a word line such that the plurality of second transistor structures 410 are connected to one word line through the first leading-out structures 504 connected with the third conductor layer 401 to achieve better gate control capability and increase switching speed.

In some examples, the semiconductor device may include a core area A and a staircase area SS that are arranged along the second direction X. The semiconductor structure 20 is located in the core area A, the second direction X intersects the first direction Z. The staircase area SS may include a plurality of staircase structures 800, where lengths of the plurality of staircase structures 800 are in gradual variation along the second direction X. The staircase structure 800 may include at least one of the conductor layers and at least one of the dielectric layers. The staircase area SS may include a plurality of second leading-out structures 502 extending along the first direction Z, where the plurality of second leading-out structures 502 are spaced apart in the second direction X, and each of the second leading-out structures 502 is connected with the conductor layer having a preset depth in the staircase structure 800.

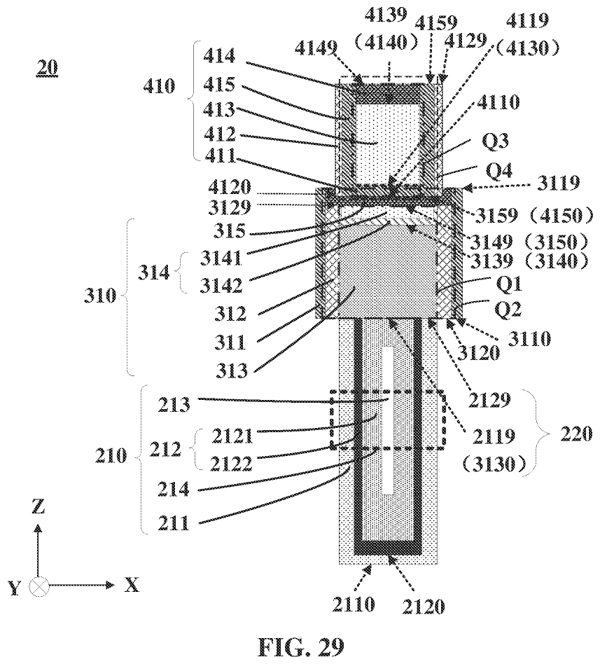

In some examples, as shown in FIG. 29, the semiconductor device may include the core area A and the staircase area SS that are arranged along the second direction X. The plurality of semiconductor structures 20 in the above examples are located in the core area A, and the plurality of semiconductor structures 20 may be spaced apart in the core area A along the second direction X by the same spacing or different spacings. The staircase area SS may include the plurality of second leading-out structures 502. The second leading-out structures 504 may extend in the staircase area SS of the stack structure 10 along the first direction Z. The plurality of second leading-out structures 502 may be spaced apart along the second direction X. The plurality of second leading-out structures 502 may be spaced apart in the staircase area SS along the second direction X by the same spacing or different spacings. Each of the second leading-out structures 502 is connected separately with the plurality of first conductor layers 201, the plurality of second conductor layers 301, and the plurality of third conductor layers 401.

In some examples, the second leading-out structures 502 may employ a conductive material that may include, but is not limited to, a combination of one or more of poly-Si, TiN, Ti, Au, W, Mo, ITO, Al, Cu, Ru, Ag, and other conductive materials.

In some examples, the semiconductor device may further include a protective layer 500 covering a face of the stack structure 10 along the first direction Z and a preset region within the staircase area SS. The preset region may include a region within the staircase area SS other than the staircase structure 800 and the second leading-out structures 502. In some examples, the semiconductor device may further include third leading-out structures 501 extending in the protective layer 500 along the first direction Z and connected with the second drain structure 414 in the second transistor structure 410.

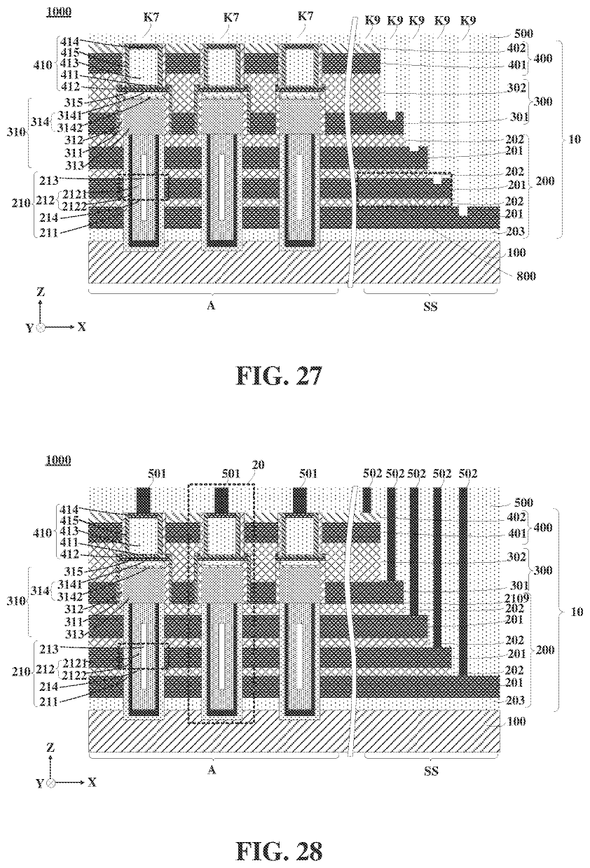

In some examples, referring to FIGS. 27 and 29, the protective layer 500 is disposed on a face of the stack structure 10 facing away from the substrate along the first direction Z. In addition, the protective layer 500 is also disposed in a region within the staircase area SS other than the staircase structure 800 and the second leading-out structures 502. A material of the protective layer 500 may employ an insulation material that may include, but is not limited to, a combination of one or more of silicon nitride, silicon oxide, or aluminum oxide. The semiconductor device may further include the third leading-out structures 501 each located on each of the second drain structures 414. That is, the plurality of third leading-out structures 501 are connected with a corresponding number of the second drain structures 414 in one-to-one correspondence.

In the examples of the present disclosure, referring to FIG. 29, the semiconductor device may include the third leading-out structures 501 extending along the first direction Z and connected with various second drain structures 414 of the core area A. The second leading-out structures 502 extending along the first direction Z and connected with various conductor layers (e.g., including the plurality of first conductor layers 201, second conductor layers 301 and third conductor layers 401) of the staircase area SS. Each of the second drain structures 414 is connected with a bit line BL through one of third leading-out structures 501 such that each semiconductor structure 20 is connected with one bit line BL. Bottoms of the first channel structures 311 of the first transistor structures 310 in the plurality of semiconductor structures 20 are jointly connected to the second conductor layer 301 as the first source structure. That is, share one source layer, and the second leading-out structures 502 connected with the second conductor layer 301 may be connected with a plate line PL such that the plurality of first transistor structures 310 are connected to one plate line PL through the second leading-out structures 502 connected with the second conductor layer 301. The bottoms of the second channel structures 415 of the second transistor structures 410 in the plurality of semiconductor structures 20 are jointly connected to the third conductor layer 401 as the second gate structure, e.g., share one gate layer. The second leading-out structures 502 connected with the third conductor layer 401 may be connected with a word line such that the plurality of second transistor structures 410 are connected to one word line through the second leading-out structures 502 connected with the third conductor layer 401 to achieve better gate control capability and increase switching speed.

Referring to FIG. 29, FIG. 29 shows an equivalent circuit diagram of a plurality of memory capacitors 214, a first transistor structure 310, and a second transistor structure 410 in one memory cell. As an example, FIG. 29 shows three memory capacitors 214. Of course, the memory cell may also include two or more memory capacitors 214. In an example, the first transistor structure 310 is connected with one end (e.g., the first electrode 212 of the memory capacitor 214) of each of the memory capacitors 214, and the other end (e.g., the dielectric layer 211 of the memory capacitor 214) of each of the memory capacitors 214 is electrically connected with the first conductor layer 201.

It should be noted that the stack structure 10 in the examples of the present disclosure may include a plurality of stack layers disposed as being stacked sequentially along the first direction Z, e.g., the first stack layer 200, the second stack layer 300, and the third stack layer 400, as shown in FIGS. 26 and 29. The first stack layer 200 may include a plurality of first conductor layers 201 and a plurality of first dielectric layers 202 that are connected alternately along the first direction Z; the second stack layer 300 may include second conductor layers 301 and second dielectric layers 302 that are connected alternately along the first direction Z; and the third stack layer 400 may include third conductor layers 401 and third dielectric layers 402 that are connected alternately along the first direction Z. Thicknesses (e.g., extending sizes along the first direction Z) of the plurality of first dielectric layers 202 in the first stack layer 200 may be approximately the same or different. The thicknesses of the plurality of first conductor layers 201 in the first stack layer 200 may be approximately the same or different. Thicknesses of the first conductor layers 201, the second conductor layers 301, and the third conductor layers 401 may be approximately the same or different. Likewise, thicknesses of the first dielectric layers 202, the second dielectric layers 302, and the third dielectric layers 402 may be approximately the same or different, which may be selected according to use-case scenario(s). Furthermore, the number of stacked layers of the first conductor layers 201 in the first stack layer 200 determines the number of the corresponding memory capacitors 214 of the same semiconductor structure 20 in the above examples. The number of the stacked layers of the first stack layer 200 may be, for example, 32 layers, 64 layers, 96 layers, 128 layers, etc. The greater the number of the stacked layers of the first stack layer 200, the higher the integration level, which means a greater number of the memory capacitors 214. The number of the stacked layers and the stacking height of the first conductor layers 201 in the first stack layer 200 may be designed specifically according to use-case scenario, to which the present disclosure imposes no specific limitations.

By disposing the plurality of first conductor layers 201 that are stacked, part of each first conductor layer 201 around the dielectric layer 211, and part of the dielectric layer 211 and the first electrode 212 opposite to the first conductor layer 201 form the memory capacitor 214 such that a memory cell including the plurality of memory capacitors 214, the first transistor structure 310 and the second transistor structure 410 can be obtained. One memory capacitor 214 can be used to store 1 bit of data, and the plurality of memory capacitors 214 can be used to store multiple bits of data. Accordingly, compared with the memory cell of a 1T1C structure in the some devices, the storage capacity of the semiconductor device 1000 is improved. On the other hand, in the examples of the present disclosure, the second transistor structure 410, the first transistor structure 310, and the capacitor structure 210 (e.g., the plurality of memory capacitors 214) in the same semiconductor structure 20 are arranged and connected sequentially along the first direction Z, which achieves a vertical configuration of transistor structures and capacitor structures 210 in the semiconductor structure 20, and greatly increases density of the memory capacitors 214, and increases storage density of the semiconductor device.

Referring to FIG. 31, a flow diagram of a fabrication method of a semiconductor device 1000 provided by examples of the present disclosure is shown. The flow may include the operations S100 and S100, with reference to the structural diagrams in FIGS. 2 to 30.

Referring to FIG. 31, at operation S100, the method may include forming a stack structure 10 including conductor layers and dielectric layers stacked alternately. The stack structure 10 as shown in FIGS. 26 and 28 is provided as an example. The relevant description of materials and numbers of the conductor layers and dielectric layers included in the stack structure 10, etc. may be referred to the description in some of the above examples, which is no longer repeated here. For ease of description, the stack structure 10 of the semiconductor device in the examples below may include a first stack layer 200, a second stack layer 300 and a third stack layer 400 as described in FIGS. 2 to 28.

At operation S200, the method may include forming at least one semiconductor structure 20 penetrating through the stack structure 10, where the semiconductor structure 20 may include a capacitor structure 210, a first transistor structure 310, and a second transistor structure 410 extending in the stack structure 10 along a first direction Z. The second transistor structure 410, the first transistor structure 310, and the capacitor structure 210 in the same semiconductor structure 20 are arranged and connected sequentially along the first direction Z.

In some examples, the operation S200 forming the at least one semiconductor structure 20 penetrating through the stack structure 10 may one or more of the following sub-operations.

For example, at sub-operation S210, the method may include forming the capacitor structure 210 extending along the first direction Z in the stack structure 10. As shown in FIGS. 2 to 7, the capacitor structure 210 extending along the first direction Z is formed in the first stack layer 200 of the stack structure 10. It should be noted that the number of layers of the first stack layer 200 illustrated is only an example, and the first stack layer 200 with other number of layers also falls within the protection scope of the present disclosure.

In some examples, the forming the capacitor structure 210 extending along the first direction Z in the stack structure 10 may include, e.g., sub-operation S211.

For example, at sub-operation S211, the method forming at least one first via K1 extending along the first direction Z in the stack structure 10, as shown in FIGS. 2 to 4.

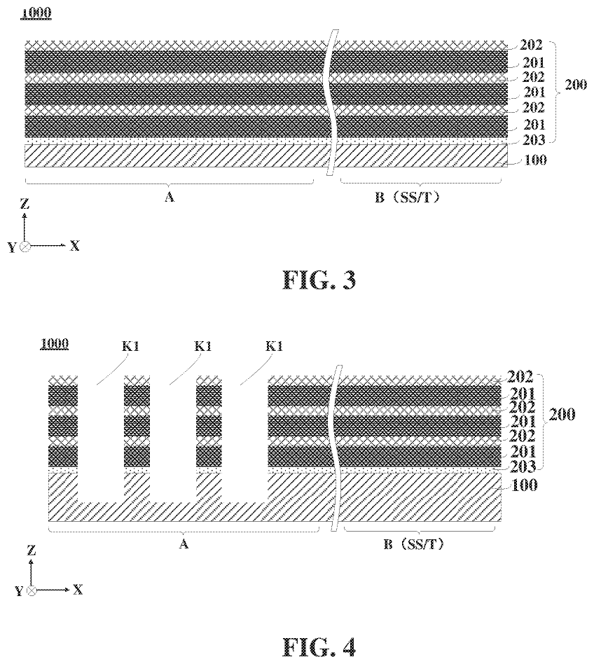

In some examples, as shown in FIGS. 2 to 3, the first stack layer 200 is formed on a side of a substrate 100 along the first direction Z. The first stack layer 200 may include a plurality of first conductor layers 201 and a plurality of first dielectric layers 202 that are disposed alternately. In some examples, the first stack layer 200 may be formed on the substrate 100 using a thin film deposition process. In an example, the thin film deposition process may include a combination of one or more of chemical vapor deposition (CVD), physical vapor deposition (PVD) and atomic layer deposition (ALD). Of course, the first stack layer 200 may further include a fourth dielectric layer 203 between the substrate and the first conductor layer 201, and the relevant description of materials of the first conductor layer 201, the first dielectric layer 202 and the fourth dielectric layer 203, etc. may be referred to the description in some of the above examples, which is no longer repeated here.

In an example, as shown in FIG. 4, the plurality of first vias K1 as described above may be formed using a dry etching process or a wet etching process. The first vias K1 may extend in a direction approaching the substrate 100 along the first direction Z.

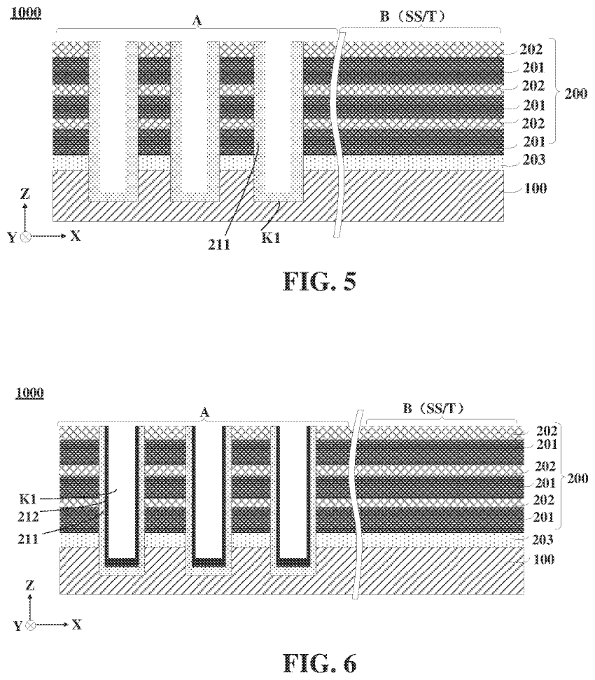

At sub-operation S212, the method may include forming dielectric layers 211 and first electrodes 212 arranged sequentially from inside to outside along a second direction X (X) within the first vias K1 to form the capacitor structure 210 extending along the first direction Z, as shown in FIGS. 5 to 7, where the second direction X intersects the first direction Z; the dielectric layer 211 is connected with the first conductor layer 201 and is disposed between the first electrode 212 and the first conductor layer 201; the capacitor structure 210 may include a plurality of memory capacitors 214 spaced apart along the first direction Z; and a third surface 2119 of the dielectric layer 211 along the first direction Z is flush with a fourth surface 2129 of the first electrode 212 along the first direction Z.

The relevant description of materials of the dielectric layer 211 and the first electrode 212 as well as the plurality of formed memory capacitors 214 in the capacitor structure 210, etc. may be referred to the description in some of the above examples, which is no longer repeated here.

In some examples, both the dielectric layer 211 and the first electrode 212 may be formed by chemical vapor deposition (CVD) (e.g., metal organic chemical vapor deposition (MOCVD), low-pressure chemical vapor deposition (LPCVD), plasma-enhanced chemical vapor deposition (PECVD), high-density plasma chemical vapor deposition (HDP-CVD), etc.). The dielectric layer 211 and the first electrode 212 may be formed by atomic layer deposition (ALD), sputtering, evaporation, or any combination thereof.

At sub-operation S220, the method may include forming the first transistor structure 310 extending along the first direction Z and in contact and connected with a first face 220 of the capacitor structure 210 along the first direction Z in the stack structure 10.

In some examples, as shown in FIGS. 8 to 16, the second stack layer 300 is formed on a side of the first stack layer 200 away from the capacitor structure 210 along the first direction Z. Then, the first transistor structure 310 connected with the capacitor structure 210 is formed in the third stack layer 400. A specific flow of forming the first transistor structure 310 may be referred to sub-operations S221 to S226 in the examples below.

In some examples, the forming the first transistor structure 310 extending along the first direction Z and in contact and connected with the first face 220 of the capacitor structure 210 along the first direction Z in the stack structure 10 may, e.g., sub-operation S221.

At sub-operation S221, the method may include forming at least one second via K2 extending along the first direction Z in the stack structure 10.

In some examples, as shown in FIG. 8, the second stack layer 300 is formed on a side of the first stack layer 200 away from the substrate along the first direction Z. The second stack layer 300 may include second conductor layers 301 and second dielectric layers 302 disposed alternately. In some examples, the second stack layer 300 may be formed on the first stack layer 200 using a thin film deposition process. In an example, the thin film deposition process may include a combination of one or more of chemical vapor deposition (CVD), physical vapor deposition (PVD) and atomic layer deposition (ALD). The relevant description of materials of the second conductor layer 301 and the second dielectric layer 302, etc. may be referred to the description in some of the above examples, which is no longer repeated here.

In an example, as shown in FIG. 9, the plurality of second vias K2 as described above may be formed using a dry etching process or a wet etching process. The second vias K2 may extend in a direction approaching the substrate 100 along the first direction Z.

At sub-operation S222, the method may include forming a first channel structure 311, a first spacing structure 312 and a first gate structure 313 that are arranged sequentially from outside to inside along a second direction X in the second via K2, as shown in FIG. 10. For instance, the second direction X intersects the first direction Z, and the first gate structure 313 is in contact and connected with the first face 220 of the capacitor structure 210 along the first direction Z.

In some examples, the first channel structure 311, the first spacing structure 312 and the first gate structure 313 may be all formed by chemical vapor deposition (CVD) (e.g., metal organic chemical vapor deposition (MOCVD), low-pressure chemical vapor deposition (LPCVD), plasma-enhanced chemical vapor deposition (PECVD), high-density plasma chemical vapor deposition (HDP-CVD), etc.). The first channel structure 311, the first spacing structure 312 and the first gate structure 313 may also be formed by atomic layer deposition (ALD), sputtering, evaporation, or any combination thereof.

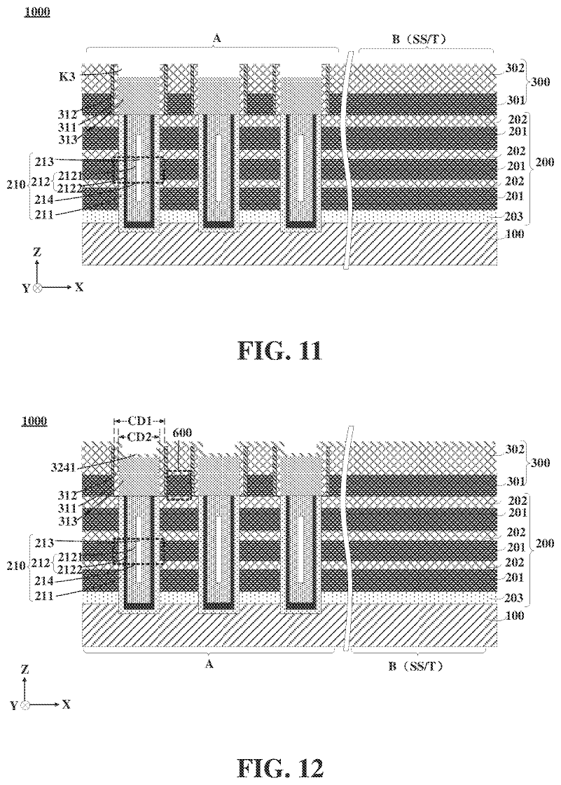

At sub-operation S223, the method may include removing part of the first gate structure 313, as shown in FIG. 11. In some examples, part of the first gate structure 313 may be removed using a dry etching process or a wet etching process.

At sub-operation S224, the method may include forming a first isolation structure 314 covering the first gate structure 313, as shown in FIG. 11.

In some examples, the first isolation structure 314 may be formed by deposition within a trench formed after the removal of part of the first gate structure 313 as shown in FIG. 11, using a thin film deposition process such as chemical vapor deposition CVD, PVD, ALD, or any combination thereof.

At sub-operation S225, the method may include removing part of the first spacing structure 312 such that a first surface 3129 of the first spacing structure 312 away from the capacitor structure 210 along the first direction Z is flush with a first end 3149 of the first isolation structure 314 away from the capacitor structure 210 along the first direction Z. In some examples, part of the first spacing structure 312 facing away from the substrate along the first direction Z may be removed using a dry etching process or a wet etching process such that the first surface 3129 of the first spacing structure 312 away from the capacitor structure 210 along the first direction Z is flush with the first end 3149 of the first isolation structure 314 away from the capacitor structure 210 along the first direction Z.

At sub-operation S226, the method may include forming a first drain structure 315 covering the first isolation structure 314 and the first spacing structure 312, as shown in FIG. 12. A first end face 3159 of the first drain structure 315 away from the capacitor structure 210 along the first direction Z is flush with a seventh surface 3119 of the first channel structure 311 away from the capacitor structure 210 along the first direction Z. The first channel structure 311 is connected with the second conductor layer 301. Part of the second conductor layer 301 connected with the first channel structure 311 serves as a first source structure of the first transistor structure 310. A second surface 3120 of the first spacing structure 312 close to the capacitor structure 210 along the first direction Z, a sixth surface 3110 of the first channel structure 311 close to the capacitor structure 210 along the first direction Z, a second side 3130 of the first gate structure 313 close to the capacitor structure 210 along the first direction Z and the first face 220 of the capacitor structure 210 along the first direction Z are flush with each other.

In some examples, the hollow pillar-shaped first channel structure 311 may include a sixth surface 3110 and a seventh surface 3119 that are disposed oppositely along the first direction Z, and a side of the first transistor structure 310 away from the capacitor structure 210 along the first direction Z is flush with the first face 220 of the capacitor structure 210 along the first direction Z.

In some examples, forming the first isolation structure 314 covering the first gate structure 313 may include forming a first isolation layer 3241 covering the stack structure 10 and the first gate structure 313. In some examples, forming the first isolation structure 314 covering the first gate structure 313 may include forming a second isolation layer 3242 on the first isolation layer. In some examples, forming the first isolation structure 314 covering the first gate structure 313 may include removing part of the second isolation layer 3242 on the stack structure 10, and part of the second isolation layer 3242 between the first spacing structures 312 and away from the capacitor structure 210. In some examples, forming the first isolation structure 314 covering the first gate structure 313 may include removing part of the first isolation layer 3241 on the stack structure 10, and part of the first isolation layer 3241 between the first spacing structures 312.

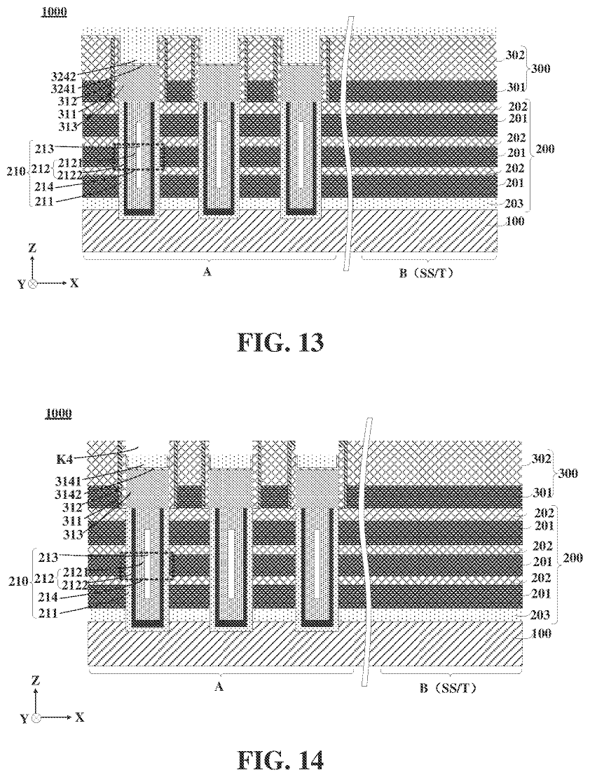

In some examples, as shown in FIG. 13, the first isolation layer 3241 and the second isolation layer 3242 may be formed using a thin film deposition process such as chemical vapor deposition CVD, PVD, ALD, or any combination thereof, and part of the first isolation layer 3241 and part of the second isolation layer 3242 may be removed using a dry etching process or a wet etching process.

At sub-operation S230, the method may include forming the second transistor structure 410 extending along the first direction Z and in contact and connected with a face of the first transistor structure 310 away from the capacitor structure 210 along the first direction Z in the stack structure 10.

In some examples, as shown in FIGS. 17 to 23, the third stack layer 400 is formed on a side of the second stack layer 300 away from the capacitor structure 210 along the first direction Z, and then the second transistor structure 410 connected with the first transistor structure 310 is formed in the third stack layer 400. A specific flow of forming the first transistor structure 310 may be referred to operations S231 to S235 in the examples below.

In some examples, the S230 forming the second transistor structure 410 extending along the first direction Z and in contact and connected with the face of the first transistor structure 310 away from the capacitor structure 210 along the first direction Z in the stack structure 10 may include sub-operation S231.

At sub-operation S231, the method may include forming at least one third via K6 extending along the first direction Z in the stack structure 10.

In some examples, as shown in FIGS. 17 and 18, the third stack layer 400 is formed on a side of the second stack layer 300 away from the substrate along the first direction Z. The third stack layer 400 may include the third conductor layers 401 and the third dielectric layers 402 disposed alternately. In some examples, the third stack layer 400 may be formed on the second stack layer 300 using a thin film deposition process. In an example, the thin film deposition process may include a combination of one or more of chemical vapor deposition (CVD), physical vapor deposition (PVD) and atomic layer deposition (ALD). The relevant description of materials of the third conductor layers 401 and the third dielectric layers 402, etc. may be referred to the description in some of the above examples, which is no longer repeated here.

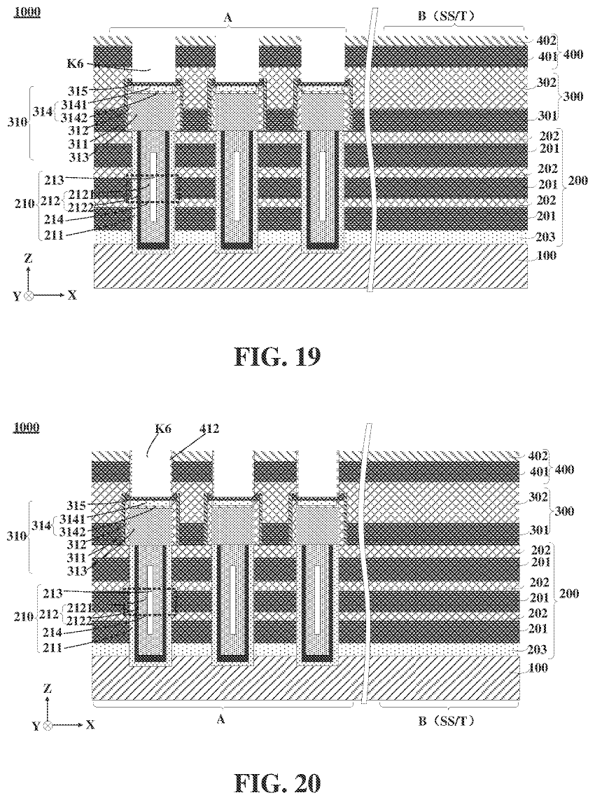

In an example, as shown in FIG. 19, the plurality of third vias K6 as described above may be formed using a dry etching process or a wet etching process. The third vias K6 may extend in a direction approaching the substrate 100 along the first direction Z.

At sub-operation S232, the method may include forming a second spacing structure 412 extending along the first direction Z within the third via K6, as shown in FIG. 20. A ninth surface 4120 of the second spacing structure 412 close to the capacitor structure 210 along the first direction Z is in contact and connected with the first end face 3159 of the first drain structure 315 away from the capacitor structure 210 along the first direction Z.

In some examples, the second spacing structure 412 may be formed by chemical vapor deposition (CVD) (e.g., metal organic chemical vapor deposition (MOCVD), low-pressure chemical vapor deposition (LPCVD), plasma-enhanced chemical vapor deposition (PECVD), high-density plasma chemical vapor deposition (HDP-CVD), etc.).

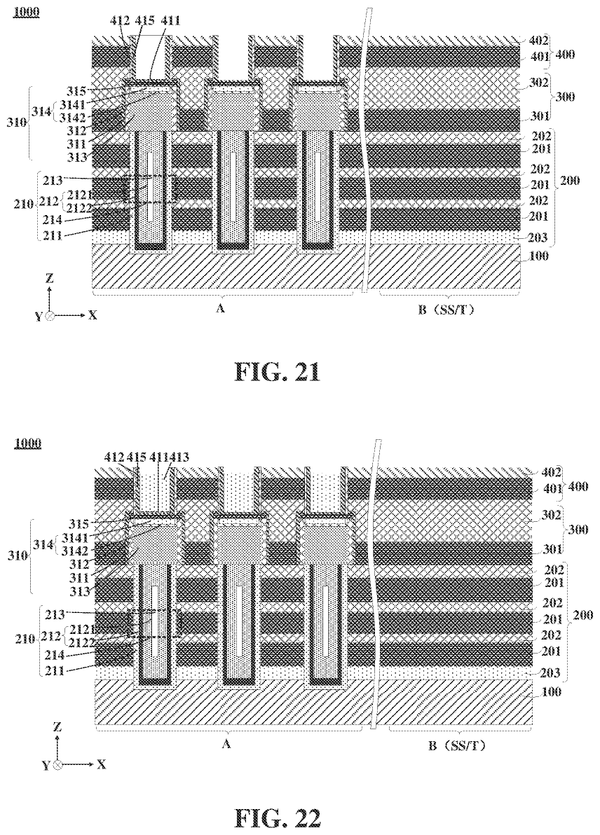

At sub-operation S233, the method may include forming a second source structure 411 between two of the second spacing structures 412, and a second channel structure 415 surrounding the second source structure 411, as shown in FIG. 21. A second side edge 4110 of the second source structure 411 close to the capacitor structure 210 along the first direction Z is in contact and connected with a first end face 3159 of the first drain structure 315 away from the capacitor structure 210 along the first direction Z.

In some examples, the second source structure 411 and the second channel structure 415 may be formed by chemical vapor deposition (CVD) (e.g., metal organic chemical vapor deposition (MOCVD), low-pressure chemical vapor deposition (LPCVD), plasma-enhanced chemical vapor deposition (PECVD), high-density plasma chemical vapor deposition (HDP-CVD), etc.).

At sub-operation S234, the method includes forming a second isolation structure 413 between the second channel structures 415, as shown in FIG. 22, where a second sidewall 4130 of the second isolation structure 413 close to the capacitor structure 210 along the first direction Z is connected with a first side edge 4119 of the second source structure 411 away from the capacitor structure 210 along first direction Z.

In some examples, the second isolation structure 413 may be formed by chemical vapor deposition (CVD) (e.g., metal organic chemical vapor deposition (MOCVD), low-pressure chemical vapor deposition (LPCVD), plasma-enhanced chemical vapor deposition (PECVD), high-density plasma chemical vapor deposition (HDP-CVD), etc.).

At sub-operation S235, the method may include forming a second drain structure 414 between the second channel structures 415, as shown in FIG. 23, where a second end 4140 of the second drain structure 414 close to the capacitor structure 210 along the first direction Z is connected with a first sidewall 4139 of the second isolation structure 413 away from the capacitor structure 210 along the first direction Z. A tenth surface 4129 of the second spacing structure 412 away from the capacitor structure 210 along the first direction Z, a thirteenth surface 4159 of the second channel structure 415 away from the capacitor structure 210 along the first direction Z, and a first end 4149 of the second drain structure 414 away from the capacitor structure 210 along the first direction Z are flush with each other.

In some examples, the stack structure 10 may include a core area A and a connection area T arranged along a second direction X. The second direction X intersects the first direction Z. The method may further include forming a plurality of fifth vias K8 in the connection area T. The method may further include forming a plurality of first leading-out structures 504 in the fifth vias K8. The first leading-out structures 504 may extend in the stack structure 10 along the first direction Z, and the plurality of first leading-out structures 504 are spaced apart in the second direction X, and each of the first leading-out structures 504 is connected separately with the conductor layer having a preset depth.

In an example, as shown in FIGS. 24, 25 and 26, a protective layer 500 may be formed on a face of the third stack layer 400 in the stack structure 10 along the first direction Z using a thin film deposition process such as chemical vapor deposition CVD, PVD, ALD or any combination thereof. By using a dry etching process or a wet etching process, part of the protective layer 500 within the connection area T in the stack structure 10 may be removed along the first direction Z and part of the conductor layers and part of the dielectric layers within the connection area T in the stack structure 10 may be removed, to form the plurality of fifth vias K8 spaced apart both along the first direction Z and the second direction X in a staircase-shaped distribution. The first leading-out structure 504 extending along the first direction Z is formed in each of the fifth vias K8 by deposition using a thin film deposition process such as chemical vapor deposition CVD, PVD, ALD, and any combination thereof. Since each of the first leading-out structures 504 is connected separately with the conductor layer having a preset depth in the connection area T, the plurality of first leading-out structures 504 formed within the connection area T are spaced apart both along the first direction Z and the second direction X in staircase-shaped distribution.

In some examples, the stack structure 10 may include a core area A and a staircase area SS arranged along the second direction X. The method may further include removing part of the conductor layers and part of the dielectric layers in the stack structure 10 to form a plurality of staircase structures 800 such that sizes of the plurality of staircase structures 800 along the first direction Z and the second direction X are in stepped variation. The method may further include forming sixth vias K9 above the staircase structure 800. The method may further include forming a plurality of second leading-out structures 502 in the sixth vias K9. The second leading-out structures 502 extend in the stack structure 10 along the first direction Z, and the plurality of second leading-out structures 502 are spaced apart in the second direction X.

In an example, as shown in FIGS. 24, 27 and 28, a protective layer 500 may be formed on a face of the third stack layer 400 in the stack structure 10 along the first direction Z using a thin film deposition process such as chemical vapor deposition CVD, PVD, ALD or any combination thereof. Then, part of the conductor layers and part of the dielectric layers within the staircase area SS in the stack structure 10 are removed along the first direction Z using a dry etching process or a wet etching process to form the plurality of staircase structures 800.

By using a dry etching process or a wet etching process, part of the staircase structures 800 may be removed and part of protective layer 500 covering the staircase structures 800 may be removed, to form the plurality of sixth vias K9 spaced apart both along the first direction Z and the second direction X in staircase-shaped distribution. The second leading-out structure 502 extending along the first direction Z is formed in each of the sixth vias K9 by deposition using a thin film deposition process such as chemical vapor deposition CVD, PVD, ALD and any combination thereof. Since each of the second leading-out structures 502 is connected separately with the conductor layer having a preset depth in the staircase structure 800, the plurality of second leading-out structures 502 formed within the staircase area SS are spaced apart both along the first direction Z and the second direction X in staircase-shaped distribution. In some examples, the method may further include forming a protective layer 500 covering a face of the stack structure 10 along the first direction Z. In some examples, the method may further include forming a plurality of fourth vias K7 above the second transistor structure 410 in the protective layer 500. In some examples, the method may further include forming third leading-out structures 501 in the fourth vias K7, where the third leading-out structures 501 extend along the first direction Z and are connected with the second drain structure 414 in the second transistor structure 410.

In an example, as shown in FIGS. 24 and 25, or as shown in FIGS. 24 and 27, the protective layer 500 may be formed on a face of the third stack layer 400 in the stack structure 10 along the first direction Z using a thin film deposition process such as chemical vapor deposition CVD, PVD, ALD or any combination thereof; part of the protective layer 500 above the second transistor structure 410 may be removed along the first direction Z using a dry etching process or a wet etching process to form the fourth vias K7; and orthographic projections of the fourth vias K7 along the second direction X are within a range of an orthographic projection of the second transistor structure 410 along the second direction X. The third leading-out structures 501 are formed in the fourth vias K7 using a thin film deposition process such as chemical vapor deposition CVD, PVD, ALD, or any combination thereof.

The semiconductor device 1000 may be a three-dimensional memory (3D Not-And (NAND) Flash), or may be part of a three-dimensional memory. When the semiconductor device 1000 is the three-dimensional memory, it may further include an array memory structure and a periphery circuit. The semiconductor device 1000 of any one of the above examples is located in the array memory structure. The array memory structure is configured to store information, and the periphery circuit may be located above or below the array memory structure, and may also be located around the array memory structure. The periphery circuit is configured to control the corresponding array memory structure. In addition, the semiconductor device 1000 may be further applied in other microelectronic devices, such as a Nor Flash, etc., without limitation. In addition, the semiconductor device 1000 of the examples of the present disclosure may be a three-dimensional memory, and may be a part of a periphery memory, which is not particularly limited.

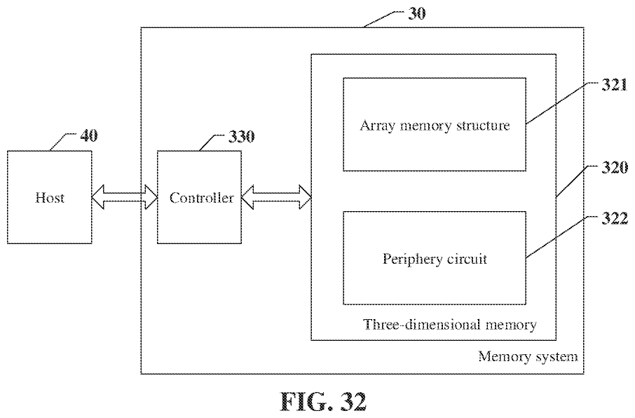

As shown in FIG. 32, examples of the present disclosure further provide a memory system which may include a controller 330 and a three-dimensional memory 320. The controller 330 is coupled to the three-dimensional memory 320 and configured to control the three-dimensional memory 320 to store data. The three-dimensional memory 320 may include the semiconductor device 1000 of any one of the above examples.

In an example, as shown in FIG. 32, the memory system 30 may include a controller 330 and one or more three-dimensional memories 320. Each of the three-dimensional memories 320 may include one or more array memory structures 321 and a periphery circuit 322. The memory system 30 may communicate with a host 40 through the controller 330. The controller 330 may be connected to the one or more three-dimensional memories 320 via channels in the one or more three-dimensional memories 320. Each three-dimensional memory 320 may be managed by the controller 330 via the channel in the three-dimensional memory 320.

The memory system 30 may be integrated in various types of storage apparatuses, for example, be included in the same package, such as a Universal Flash Storage (UFS) package or an Embedded Multi Media Card (eMMC) package. That is to say, the memory system 30 may be applied and packaged into the above-mentioned electronic apparatus. The memory system 30 may be, for example, integrated in a memory card, and the memory system 30 may be also, for example, integrated in a solid-state drive (SSD).

The memory card includes one of a PC (Personal Computer Memory Card International Association (PCMCIA)) card, a Compact Flash (CF) card, a Smart Media (SM) card, a memory stick, a Multimedia Card (MMC), a Secure Digital Memory Card (SD) card, and a UFS.

In some examples, in the memory system 30, the controller 330 is configured for operating in a low duty-cycle environment, such as Secure Digital (SD) cards, Compact Flash (CF) cards, Universal Serial Bus (USB) flash drives, or other media for use in electronic apparatuses, such as personal computers, digital cameras, mobile phones, etc.

In some other examples, in the memory system 30, the controller 330 is configured for operating in high duty-cycle environment SSDs or eMMCs used as data memories for mobile apparatuses, such as smartphones, tablet computers, laptop computers, etc., and enterprise memory arrays.

In some examples, the controller 330 may be configured to manage the data stored in the three-dimensional memory 320 and communicate with an external apparatus (e.g., a host).

In some examples, the controller 330 may be further configured to control operations of the three-dimensional memory 320, such as read, erase, and program operations.

In some examples, the controller 330 may be further configured to manage various functions with respect to data stored or to be stored in the three-dimensional memory 320, including at least one of bad-block management, garbage collection, logical-to-physical address conversion, and wear leveling.

In some examples, the controller 330 is further configured to process error correction codes with respect to the data read from or written to the three-dimensional memory 320.

It is readily understood that the controller 330 may also perform any other suitable functions, for example, formatting the three-dimensional memory 320. For another example, the controller 330 may communicate with an external apparatus (e.g., a host) through at least one of various interface protocols.

It should be noted that the interface protocols include at least one of a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol and a Firewire protocol.

The above-mentioned controller 330 may be, for example, a central processing unit (CPU), a general-purpose processor, a digital signal processor (DSP), an disclosure-specific integrated circuit (ASIC), a field programmable gate array (FPGA) or other programmable logic devices, transistor logic devices, hardware components, or any combination thereof.

It should be noted that the above-mentioned periphery circuit 322 may include one or more periphery devices. In an example, the above-mentioned periphery devices may include, for example, a page buffer, a decoder (e.g., a row decoder and a column decoder), a sense amplifier, a driver (e.g., a word line driver), or any active (or passive) component (e.g., a transistor, a diode, a resistor, and a memory capacitor 214, etc.) of the circuits.

The above-mentioned periphery devices may also include any other circuits compatible with advanced logic processes. In an example, the periphery devices include at least one of a logic circuit (e.g., a processor and a programmable logic device) or a memory circuit (e.g., a static random access memory).

A semiconductor device 1000 and a fabrication method thereof and a memory system 30 provided by the examples of the present disclosure are introduced above in detail. The principle and implementations of the present disclosure are set forth herein by applying specific individual cases. The descriptions of the above examples are only to help understand the methods and core ideas of the present disclosure. Meanwhile, those skilled in the art may make changes over the specific implementations and disclosure scope according to the ideas of the present disclosure. To sum up, the contents of this specification should not be interpreted as limitations to the present disclosure.

What is claimed is:

1. A semiconductor device, comprising:
a stack structure comprising conductor layers and dielectric layers stacked alternately along a first direction; and
at least one semiconductor structure penetrating through the stack structure,
wherein the semiconductor structure comprises:
a capacitor structure, a first transistor structure, and a second transistor structure extending in the stack structure along the first direction, and
wherein the second transistor structure, the first transistor structure, and the capacitor structure in a same semiconductor structure are arranged and connected sequentially along the first direction.

2. The semiconductor device of claim 1, wherein the capacitor structure comprises a plurality of memory capacitors that are arranged spaced apart along the first direction.

3. The semiconductor device of claim 2, wherein:
the memory capacitors each comprise a first electrode and a dielectric layer, and
the dielectric layer is connected with a first conductor layer and is disposed between the first electrode and the first conductor layer.

4. The semiconductor device of claim 3, wherein:
along a radial direction of the capacitor structure, the first electrode comprises a plurality of layers of sub-electrodes, and
the radial direction intersects the first direction.

5. The semiconductor device of claim 1, wherein the first transistor structure comprises:
a first gate structure connected with a first face of the capacitor structure along the first direction;
a first isolation structure connected with a first side of the first gate structure along the first direction;
a first spacing structure surrounding the first gate structure and the first isolation structure;
a first drain structure connected with a first end of the first isolation structure along the first direction and a first surface of the first spacing structure along the first direction; and
a first channel structure surrounding the first spacing structure and the first drain structure, the first channel structure being connected with a second conductor layer, and part of the second conductor layer connected with the first channel structure serving as a first source structure of the first transistor structure.

6. The semiconductor device of claim 5, wherein:
a size of the first channel structure along a second direction is greater than a size of the capacitor structure along the first direction, and
the second direction intersects the first direction.

7. The semiconductor device of claim 5, wherein a size of the first gate structure in the first direction is greater than a size of the second conductor layer connected with the first gate structure in the first direction.

8. The semiconductor device of claim 6, wherein:
the first isolation structure comprises an isolation trench structure and a dielectric material layer within the isolation trench structure, and
a size of the first drain structure along the second direction is greater than a size of the dielectric material layer along the second direction.

9. The semiconductor device of claim 5, wherein the second transistor structure comprises:
a second source structure connected with a first end face of the first drain structure along the first direction;
a second isolation structure connected with a first side edge of the second source structure along the first direction;
a second drain structure connected with a first sidewall of the second isolation structure along the first direction;
a second channel structure surrounding the second source structure, the second isolation structure and the second drain structure; and
a second spacing structure surrounding the second channel structure, the second spacing structure being connected with a third conductor layer, and part of the third conductor layer connected with the second spacing structure serving as a second gate structure of the second transistor structure.

10. The semiconductor device of claim 9, wherein:
an orthographic projection of the second spacing structure on the stack structure is within a region surrounded by an outer side face of the first channel structure, and
an outer side face of the second spacing structure is spaced from the outer side face of the first channel structure by a preset distance.

11. The semiconductor device of claim 3, wherein a material of the dielectric layer includes one or more of a ferroelectric material and an anti-ferroelectric material.

12. The semiconductor device of claim 4, wherein a material of sub-electrodes in the layers of sub-electrodes includes one or more of titanium nitride and polysilicon.

13. The semiconductor device of claim 9, comprising:
a core area and a connection area that are arranged along a second direction,
wherein the semiconductor structure is located in the core area,
wherein the second direction intersects the first direction,
wherein the connection area comprises:
a plurality of first leading-out structures extending in the stack structure along the first direction,
wherein the plurality of first leading-out structures are spaced apart in the second direction, and
wherein each of the first leading-out structures is connected separately with the conductive layers having a preset depth.

14. The semiconductor device of claim 13, wherein each of the first leading-out structures comprises:
a conductive contact extending along the first direction; and
an insulation barrier layer surrounding the conductive contact.

15. The semiconductor device of claim 14, further comprising:
a protective layer covering a face of the stack structure along the first direction; and
third leading-out structures extending in the protective layer along the first direction and connected with the second drain structure in the second transistor structure.

16. The semiconductor device of claim 9, comprising:
a core area and a staircase area that are arranged along a second direction,
wherein the semiconductor structure is located in the core area,
wherein the second direction intersects the first direction, and
wherein the staircase area comprises:
a plurality of staircase structures,
wherein lengths of the plurality of staircase structures along the second direction are in gradual variation, and
wherein the staircase structures each comprises at least one of the conductor layers and at least one of the dielectric layers; and
a plurality of second leading-out structures extending along the first direction,
wherein the plurality of second leading-out structures are arranged spaced apart in the second direction, and
wherein each of the second leading-out structures is connected separately with the conductive layers having a preset depth in the staircase structure.

17. The semiconductor device of claim 16, further comprising:
a protective layer covering a face of the stack structure along the first direction and a preset region within the staircase area, the preset region comprising a region within the staircase area other than the staircase structures and the second leading-out structures; and
third leading-out structures extending in the protective layer along the first direction and connected with the second drain structure in the second transistor structure.

18. A method of fabricating a semiconductor device, comprising:
forming a stack structure comprising conductor layers and dielectric layers stacked alternately; and
forming at least one semiconductor structure penetrating through the stack structure,
wherein the semiconductor structure comprises a capacitor structure, a first transistor structure, and a second transistor structure that extend in the stack structure along a first direction,
wherein the second transistor structure, the first transistor structure, and the capacitor structure in a same semiconductor structure are arranged and connected sequentially along the first direction.

19. The method of claim 18, wherein the forming the at least one semiconductor structure penetrating through the stack structure comprises:
forming the capacitor structure extending along the first direction in the stack structure;
forming the first transistor structure extending along the first direction and in contact and connected with a first face of the capacitor structure along the first direction in the stack structure; and
forming the second transistor structure extending along the first direction and in contact and connected with a face of the first transistor structure away from the capacitor structure along the first direction in the stack structure.

20. A memory system, comprising:
a three-dimensional memory, comprising:
a stack structure comprising conductor layers and dielectric layers stacked alternately along a first direction; and
at least one semiconductor structure penetrating through the stack structure, the semiconductor structure comprising:
a capacitor structure, a first transistor structure, and a second transistor structure extending in the stack structure along the first direction, the second transistor structure, the first transistor structure, and the capacitor structure in a same semiconductor structure being arranged and connected sequentially along the first direction; and
a controller coupled to the three-dimensional memory and configured to control the three-dimensional memory to store data.
